(19) United States
(12) Patent Application Publication
(10) Pub. No.: US 2025/0197996 A1
(43) Pub. Date: Jun. 19, 2025

(54) LOW-K DIELECTRIC PROTECTION DURING PLASMA DEPOSITION OF SILICON NITRIDE

(71) Applicant: Lam Research Corporation, Fremont, CA (US)

(72) Inventors: Awnish Gupta, Hillsboro, OR (US); Dustin Zachary Austin, Tigard, OR (US); Gopinath Bhimarasetti, Portland, OR (US); Bo Gong, Sherwood, OR (US); Andrew John McKerrow, Lake Oswego, OR (US); Jennifer Leigh Petraglia, Lake Oswego, OR (US)

(21) Appl. No.: 18/847,652

(22) PCT Filed: Mar. 15, 2023
(86) PCT No.: PCT/US2023/064491

§ 371 Date: Sep. 16, 2024

Related U.S. Application Data
(60) Provisional application No. 63/375,447, filed on Sep. 13, 2022.
(60) Provisional application No. 63/269,597, filed on Mar. 18, 2022.

(51) Int. Cl. C23C 16/455; C23C 16/02; C23C 16/34; C23C 16/52; H01L 21/02

(52) U.S. Cl. CPC C23C 16/45536; C23C 16/0272; C23C 16/345; C23C 16/45544; C23C 16/45553; C23C 16/52; H01L 21/02126; H01L 21/02211; H01L 21/02274; H01L 21/0228

(57) ABSTRACT

Methods and apparatuses for depositing silicon nitride using a plasma over low-k dielectric material while protecting the low-k dielectric material are provided. The methods comprise providing a substrate having a dielectric material deposited thereon, depositing a protective layer on the dielectric material in a plasma-free environment, and after depositing the protective layer, exposing the substrate to a first plasma to deposit a first silicon nitride while converting at least a portion of the protective layer to second silicon nitride.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Semiconductor fabrication processes involve deposition of silicon-containing materials, including silicon nitride materials on low-k dielectric materials. It is challenging to reduce damage to the low-k dielectric during deposition of silicon nitride while forming high quality silicon nitride.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

One aspect involves a method for processing substrates, the method including: providing a substrate having a dielectric material deposited thereon; depositing a protective layer on the dielectric material in a plasma-free environment; and after depositing the protective layer, exposing the substrate to a first plasma to deposit a first silicon nitride while converting at least a portion of the protective layer to second silicon nitride.

In various embodiments, the protective layer is deposited by thermally decomposing a deposition precursor on a surface of the substrate.

In various embodiments, the protective layer is deposited by exposing the substrate to a deposition precursor; and heating the substrate to a temperature sufficient to decompose the deposition precursor onto a surface of the substrate.

In various embodiments, the protective layer is deposited by temporally alternating pulses of exposing the substrate to a deposition precursor; and exposing the substrate to an inert gas. In some embodiments, the substrate is heated to a temperature of at least about 500° C.

In various embodiments, exposing the substrate to the first plasma includes generating the first plasma using one or more nitrogen-containing gases. In some embodiments, the nitrogen-containing gases is one of nitrogen, ammonia, and combinations thereof. In some embodiments, the first plasma is generated using a plasma power of about 500 W to about 6000 kW for a single-wafer chamber. In some embodiments, the second silicon nitride is deposited by performing one or more deposition cycles. For example, in some embodiments, one of the one or more deposition cycles includes using temporally alternating pulses of exposure to a silicon-containing precursor and exposure to a nitrogen-containing plasma. In some embodiments, one of the one or more deposition cycles includes using temporally separated pulses of exposure to a silicon-containing precursor, exposure to the first plasma generated from igniting nitrogen gas, and exposure to a third plasma generated from igniting a mixture of ammonia and nitrogen gas.

In various embodiments and any embodiment described above, during the depositing of the protective layer, less than about 1 Å of the dielectric material is consumed.

In various embodiments and any embodiment described above, the dielectric material is silicon oxycarbide.

In various embodiments and any embodiment described above, the protective layer is deposited directly on the dielectric material.

In various embodiments and any embodiment described above, all of the protective layer is converted to the second silicon nitride.

In various embodiments, the protective layer is deposited by decomposing a deposition precursor on a surface of a substrate to form a decomposed film; and exposing the decomposed film to a second plasma to form the protective layer. In some embodiments, the second plasma is generated by igniting an inert gas and the protective layer is densified. In some embodiments, the second plasma is generated by igniting an oxygen-containing or nitrogen-containing gas and the protective layer is an oxide or nitride. In some embodiments, exposing the decomposed film to the second plasma includes exposing the decomposed film to an inert gas plasma and then exposing the decomposed film to an oxygen-containing or nitrogen-containing plasma. In some embodiments, the method also includes repeating decomposing the deposition precursor and exposing the decomposed film to the inert gas plasma and the oxygen-containing or nitrogen-containing plasma.

In various embodiments, the deposition precursor is diisopropylaminosilane.

In various embodiments, the deposition precursor is bis(tertiarybutylamino) silane.

Another aspect involves a method for processing substrates, the method including: providing a substrate having a silicon oxynitride material deposited thereon to a process chamber; introducing a first silicon-containing precursor to the process chamber at process conditions sufficient to decompose the first silicon-containing precursor and form decomposed first silicon-containing precursor on a surface of the substrate in a plasma-free environment to form a protective layer comprising the decomposed first silicon-containing precursor; after forming the protective layer, introducing a second silicon-containing precursor to the process chamber to form an adsorbed layer of the second silicon-containing precursor on a surface of the protective layer; and introducing a nitrogen-containing plasma to the process chamber to convert the second silicon-containing precursor to silicon nitride and convert at least a portion of the protective layer to silicon nitride.

In various embodiments, at least one of the first and the second silicon-containing precursors is diisopropylaminosilane.

In various embodiments, at least one of the first and the second silicon-containing precursors is bis(tertiarybutylamino) silane.

In various embodiments, the first silicon-containing precursor and the second silicon-containing precursor are the same.

In various embodiments, the first silicon-containing precursor and the second silicon-containing precursor are different.

In various embodiments, the nitrogen-containing plasma is generated by igniting nitrogen gas, ammonia gas, or a mixture of nitrogen gas and ammonia gas.

Another aspect involves an apparatus for processing substrates, the apparatus including:

one or more process chambers, each process chamber including a chuck; one or more gas inlets into the process chambers and associated flow-control hardware; and a controller having at least one processor and a memory, whereby the at least one processor and the memory are communicatively connected with one another, the at least one processor is at least operatively connected with the flow-control hardware, and the memory stores computer-executable instructions for controlling the at least one processor to at least control the flow-control hardware to: cause introduction of a first silicon-containing precursor to the one or more process chambers for a duration sufficient to adsorb at least some of the first silicon-containing precursor to adsorb to a surface of a substrate without igniting a plasma; cause heating of the chuck to decompose the first silicon-containing precursor and form a protective layer on the surface of the substrate; cause introduction of a second silicon-containing precursor to the one or more process chambers for a duration sufficient to adsorb at least some of the second silicon-containing precursor to adsorb to a surface of a substrate without igniting a plasma; and cause generation of a plasma using a nitrogen-containing gas both convert the second silicon-containing precursor to silicon nitride and convert at least a portion of the protective layer to silicon nitride.

These and other aspects are described further below with reference to the drawings.

### BRIEF DESCRIPTION OF THE DRAWINGS

FIGS. 1A-1C are process flow diagrams depicting operations that may be performed in accordance with certain disclosed embodiments.

FIGS. 2A-2E-2 are schematic illustrations of substrates undergoing processing in accordance with certain disclosed embodiments.

FIG. 3 is a schematic diagram of an example process chamber for performing certain disclosed embodiments.

FIG. 4 is a schematic diagram of an example process tool for performing certain disclosed embodiments.

FIG. 5 is a schematic diagram of an example process tool for performing certain disclosed embodiments.

FIGS. 6-8 are charts showing silicon oxynitride loss for various experiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Semiconductor fabrication processing may involve depositing materials onto a surface having dielectric material. In some embodiments, low-k dielectric material may be used to fabricate certain structures. Low-k dielectric material may have a k value of about 4.4 to about 4.7. In some cases, low-k dielectric material have low hardness, or low modulus or both. A low modulus for low density SiOC material may have a modulus of about 10 GPa or lower. A low modulus for high density SiOC material may have a modulus of about 150 GPa or lower. For example, in some cases, low-k dielectric material may be used as interconnecting insulators for resistive-capacitive (RC) delay reduction. In some cases, it may be desirable to deposit high quality material over low-k dielectric material. For example, it may be desirable to deposit high quality silicon nitride (SiN) over a silicon oxycarbide material (SiOC). However, depositing SIN may involve exposing the semiconductor substrate to a plasma. When the substrate is exposed to plasma, the exposed SiOC material may thus be exposed to plasma, which may damage the surface of the SiOC, which may be referred to as “SiOC loss.” Damage to SiOC by plasma can cause the device to have increased leakage current, decreased breakdown voltage, increased dielectric breakdown over time, and increase in dielectric constant, which all affect device performance.

While SiN may be deposited using thermal atomic layer deposition (ALD) in a furnace to prevent damage to the low-k dielectric material, furnace deposition has limitations in its ability to tune and control film properties of the deposited SiN. Alternatively, plasma-based processes that use remote plasma may be used but controllability of the film properties may also be limited, and in some cases, damage to the low-k dielectric material may still be present.

Provided herein are methods and apparatuses for depositing SiN on low-k dielectric materials while minimizing or eliminating SiOC loss. Deposition using certain disclosed embodiments can still utilize deposition of SiN using in-situ or remote plasma processes, resulting in deposition of high quality SiN with a wide tunability window, allowing more controlled film deposition.

Certain disclosed embodiments involve depositing a protective layer on the low-k dielectric material using a thermal, plasma-free process, then depositing SiN on the protective layer using a plasma-based process, which simultaneously deposits SiN and converts at least part of the protective layer to SiN. The resulting substrate structure shows substantially indistinguishable properties between the converted SiN and the plasma as—deposited SiN as both materials have similar film properties and are both high quality films. Additionally, in some embodiments, a portion of the protective layer may be intentionally left at the low-k dielectric and SiN interface to control wet etch rate and other film properties.

Certain disclosed embodiments result in SiOC loss of less than about 1 Å or 0 Å or results in no measurable SiOC loss. Certain disclosed embodiments may be implemented in-situ. In some embodiments, deposition of the protective layer and the SiN are performed without breaking vacuum, or are performed in the same process chamber, or are performed in the same tool, or any combination thereof. In some embodiments, deposition of the protective layer and the SiN are performed in a single process chamber. Certain disclosed embodiments may be performed in single-wafer chambers.

Techniques described herein involve thermal atomic layer deposition (ALD). That is, in various embodiments, the reaction between an aminosilane or halosilane and an nitrogen-containing reactant to form silicon nitride is performed without igniting a plasma. ALD is a technique that deposits thin layers of material using sequential self-limiting reactions. Typically, an ALD cycle includes operations to deliver and adsorb at least one reactant to the substrate surface, and then react the adsorbed reactant with one or more reactants to form the partial layer of film. As another example, a silicon nitride deposition cycle may include the following operations: (i) delivery/adsorption of a silicon-containing precursor, (ii) purging of the silicon-containing precursor from the chamber, (iii) delivery of a nitrogen-containing gas, and (iv) purging of the nitrogen-containing gas from the chamber. In various embodiments, delivery/adsorption of a deposition precursor and delivery of a reactant gas are delivered in temporally alternating pulses. Temporally alternating pulses is defined as pulses that are introduced at different times, one after another. For example, an on/off sequence of temporally alternating pulses may include the following operations in this order: (1) turning on the flow of a silicon-containing precursor, (2) turning off the flow of the silicon-containing precursor, (3) turning on the flow of a nitrogen-containing reactant, and (4) turning off the flow of the nitrogen-containing reactant. While such sequence is provided as an example, it will be understood that exposures may be performed in a different order in one or more cycles, and other gases other than a silicon-containing precursor or a nitrogen-containing reactant may be used, and that there may be pauses or purges or other intervening exposures between the temporally alternating pulses.

Unlike a chemical vapor deposition (CVD) technique, ALD processes use surface mediated deposition reactions to deposit films on a layer-by-layer basis. In one example of an ALD process, a substrate surface that includes a population of surface active sites is exposed to a gas phase distribution of a first precursor, such as a silicon-containing precursor, in a dose provided to a chamber housing a substrate. Molecules of this first precursor are adsorbed onto the substrate surface, including chemisorbed species and/or physiosorbed molecules of the first precursor. It should be understood that when the compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. After a first precursor dose, the chamber is then evacuated to remove most or all of the silicon-containing precursor remaining in gas phase so that mostly or only the adsorbed species remain. In some implementations, the chamber may not be fully evacuated. For example, the chamber may be evacuated such that the partial pressure of the first precursor in gas phase is sufficiently low to mitigate a reaction. A second reactant, such as a nitrogen-containing reactant, is introduced to the chamber so that some of these molecules react with the silicon-containing precursor adsorbed on the surface. In some processes, the second reactant reacts immediately with the adsorbed silicon-containing precursor. The chamber may then be evacuated again to remove unbound nitrogen-containing reactant molecules. As described above, in some embodiments the chamber may not be completely evacuated. Additional ALD cycles may be used to build film thickness.

In certain embodiments, an ALD first precursor dose partially saturates the substrate surface. In some embodiments, the dose phase of an ALD cycle concludes before the precursor contacts the substrate to evenly saturate the surface. Typically, the precursor flow is turned off or diverted at this point, and only purge gas flows. By operating in this sub saturation regime, the ALD process reduces the cycle time and increases throughput. However, because precursor adsorption is not saturation limited, the adsorbed precursor concentration may vary slightly across the substrate surface. Examples of ALD processes operating in the sub-saturation regime are provided in U.S. patent application Ser. No. 14/061,587 (now U.S. Pat. No. 9,355,839), filed Oct. 23, 2013, titled “SUB-SATURATED ATOMIC LAYER DEPOSITION AND CONFORMAL FILM DEPOSITION,” which is incorporated herein by reference in its entirety.

In some implementations, ALD methods may include plasma activation. However, in thermal ALD processes described herein, plasma is not ignited. As described herein, the ALD methods and apparatuses described herein may be conformal film deposition (CFD) methods, which are described generally in U.S. patent application Ser. No. 13/084,399 (now U.S. Pat. No. 8,728,956), filed Apr. 11, 2011, and titled “PLASMA ACTIVATED CONFORMAL FILM DEPOSITION,” and in U.S. patent application Ser. No. 13/084,305, filed Apr. 11, 2011, and titled “SILICON NITRIDE FILMS AND METHODS,” which are herein incorporated by reference in their entireties.

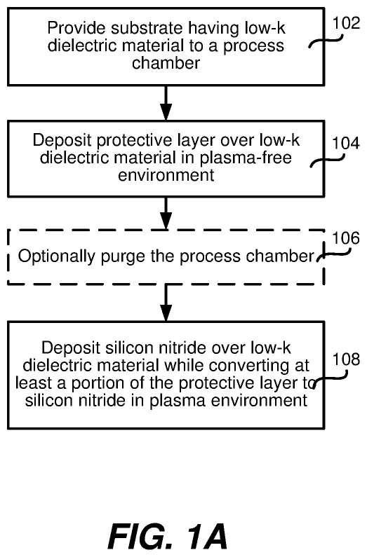

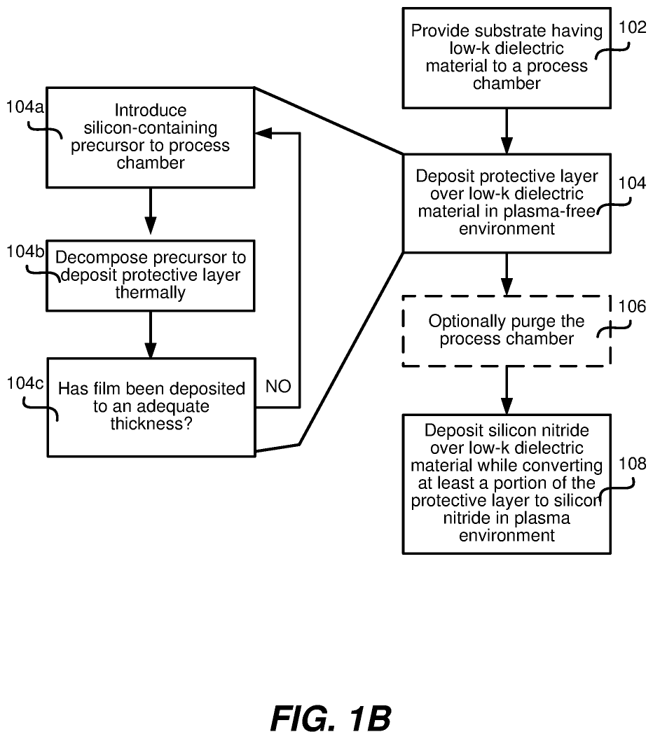

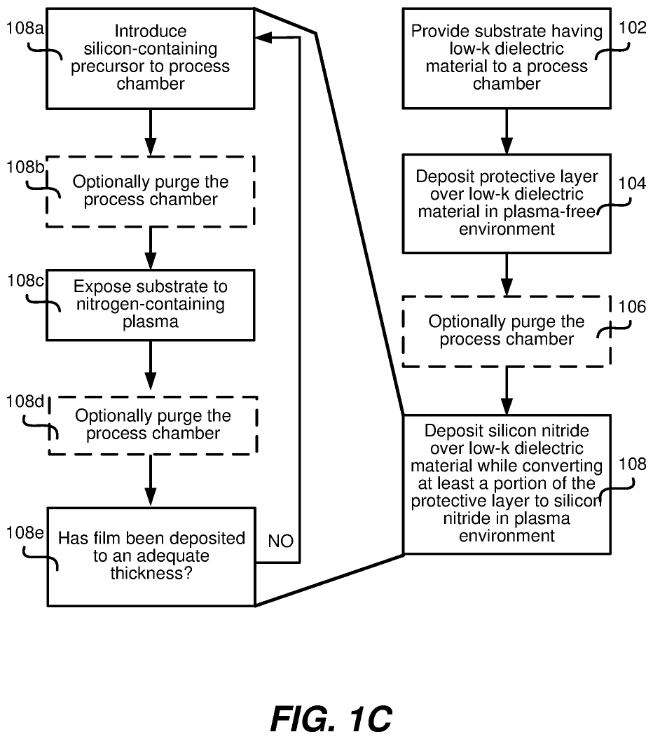

FIG. 1A is a process flow diagram depicting operations that may be performed in accordance with certain disclosed embodiments. In operation 102, a substrate having a low-k dielectric material deposited thereon is provided to a process chamber. In various embodiments, the process chamber is a single-wafer chamber. In some embodiments, the process chamber is a station within a multi-station chamber. Process conditions described herein are suitable for a single-wafer chamber.

The process chamber may be set to a chamber pressure about 5 mTorr to about 25 Torr or about 10 Torr to about 25 Torr. Such chamber pressures may be used throughout operations 104-108 as described herein. In some embodiments, chamber pressure may be different during different operations. The chamber pressure may also depend on the chemistries selected for various operations described herein.

The substrate may be heated to a substrate temperature about 25° C. to about 800° C., or about 500° C. to about 700° C., or at least about 650° C. during operations 104-108. It will be understood that substrate temperature as used herein refers to the temperature that the pedestal holding the substrate is set at and that in some embodiments, the substrate when provided to the process chamber on the pedestal may be heated to the desired substrate temperature prior to processing the substrate. The substrate temperature may be the same throughout operations 102-108 as described herein.

The substrate may be any suitable substrate. The substrate may be a silicon wafer, e.g., a 200-mm wafer, a 300-mm wafer, including wafers having one or more layers of material, such as dielectric, conducting, or semi-conducting material deposited thereon. Non-limiting examples of under layers include dielectric layers and conducting layers, e.g., silicon oxides, silicon nitrides, silicon carbides, metal oxides, metal nitrides, metal carbides, and metal layers. In some embodiments, the substrate includes silicon oxide and silicon. In some embodiments, the substrate includes a partially fabricated 3D-NAND structure.

In some embodiments, the feature(s) may have an aspect ratio of at least about 1:1, at least about 2:1, at least about 4:1, at least about 6:1, at least about 10:1, or at least about 20:1, or at least about 50:1, or at least about 100:1, or at least about 150:1, or at least about 200:1, or higher. The feature(s) may also have a dimension near the opening, e.g., an opening diameter or line width of between about 10 nm to 500 nm, for example between about 25 nm and about 300 nm. Disclosed methods may be performed on substrates with feature(s) having an opening less than about 150 nm. A via, trench or other recessed feature may be referred to as an unfilled feature or a feature. According to various embodiments, the feature profile may narrow gradually and/or include an overhang at the feature opening. A re-entrant profile is one that narrows from the bottom, closed end, or interior of the feature to the feature opening. A re-entrant profile may be generated by asymmetric etching kinetics during patterning and/or the overhang due to non-conformal film step coverage in the previous film deposition, such as deposition of a diffusion barrier. In various examples, the feature may have a width smaller in the opening at the top of the feature than the width of the bottom of the feature. One or more features may have a high aspect ratio, which is defined as having an aspect ratio of greater than about 100:1 or greater than about 150:1 or greater than about 180:1.

In some embodiments, the substrate may be partially fabricated for forming a memory device. In some embodiments, exposed regions of the substrate include silicon-containing surfaces, including but not limited to low-k dielectric material, silicon oxide, silicon nitride, silicon oxynitride, silicon oxycarbide, silicon carbonitride, and silicon carbide. In some embodiments, exposed regions of the substrate include silicon oxynitride.

In operation 104, a protective layer is deposited over the dielectric material in a plasma-free environment. In various embodiments, the dielectric material is low-k material. In various embodiments, the protective layer is deposited on the dielectric material. In some embodiments, the protective layer is deposited directly on the dielectric material. In some embodiments, the protective layer is deposited directly on the dielectric material without any intervening layers between the protective layer and the dielectric material. During deposition of the protective layer, the amount of low-k dielectric material consumed is less than about 1 Å or about 0 Å or OÅ. The protective layer is deposited in a plasma-free environment to reduce and/or eliminate damage to the low-k dielectric material. The protective material may be a layer formed by a decomposition process or by a cyclic process or a combination thereof.

An example of a method for depositing the protective material is shown in FIG. 1B. In FIG. 10B, operation 104 includes three operations, operation 104a, operation 104b, and operation 104c. Although this is provided as an example for depositing the protective layer in operation 104, it will be understood that other techniques or variations of operations 104a-104c may be used in some embodiments.

In operation 104a, a silicon-containing precursor is introduced to the process chamber. In various embodiments, the silicon-containing precursor is a silane. Non-limiting examples of silanes that may be used include but are not limited to substituted and unsubstituted silanes, halosilanes, aminosilanes, organosilanes, alkylsilanes, alkylaminosilanes, and alkylhalosilanes.

Additional example silicon-containing precursors are described further elsewhere herein in the Definitions and Precursors section. In some embodiments, the silicon-containing precursor is diisopropylaminosilane (DIPAS).

The silicon-containing precursor is introduced at a flow rate of about 100 sccm to about 2000 sccm for a single-wafer chamber. In some embodiments, a carrier gas or a push gas is also flowed with the silicon-containing precursor. The carrier gas or push gas may be nitrogen gas or argon in some embodiments. The carrier gas or push gas may be flowed at a flow rate of about 300 sccm to about 1500 sccm for a single-wafer chamber. Operation 104a may be performed for a duration of about 0.1 second to about 10 seconds. In some embodiments, additional nitrogen gas may be introduced with the silicon-containing gas as a dilution gas, for pressure stability, or both.

In some embodiments, additional nitrogen gas is flowed at a flow rate of about 500 sccm to about 10000 sccm for a single-wafer chamber. The pressure of the process chamber during operation 104a may be about 5 Torr to about 25 Torr.

In one example, during operation 104a, an aminosilane precursor is introduced at a flow rate of about 600 sccm in a chamber having a pressure of about 22 Torr for an exposure time of about 1 second using a push gas having a flow rate of about 1500 sccm.

Operation 104a is performed without igniting a plasma. In some embodiments, operation 104a is performed in a plasma-free environment.

In operation 104b, the silicon-containing precursor is decomposed to form a protective layer thermally on a surface of the substrate. The protective layer includes decomposed silicon-containing precursor. Thermal decomposition is performed such that the pedestal is set at a temperature that is at least the decomposition temperature or greater than the decomposition temperature of the precursor(s) used during decomposition. Operation 104b may be performed by heating the substrate while introducing the silicon-containing precursor in operation 104a to allow the silicon-containing precursor to decompose onto the surface of the substrate. Heating the substrate may be performed by setting the temperature of the pedestal holding the substrate to a temperature of at least about 400° C., or at least about 500° C., or at least about 650° C., or at least about 750° C., or about 500° C. to about 700° C. or about 650° C. or higher, depending on the silicon-containing precursor used.

During this operation or shortly thereafter, a purging operation may be performed. In some embodiments, the silicon-containing precursor may continue to flow. In some embodiments, operation 104b involves stopping flow of the silicon-containing precursor and introducing flow of an inert gas or a purge gas to decompose silicon-containing precursor molecules that are adsorbed onto a surface of the substrate or silicon-containing precursor molecules in a processing region of the process chamber over the substrate in gas phase.

Example inert or purge gases include but are not limited to nitrogen gas and argon. Flow rate of the inert or purge gas during operation 104b is about 1000 sccm to about 40000 sccm. Introduction of the inert or purge gas may be performed for a duration of about 0.1 second to about 10 seconds. During operation 104b, the chamber pressure may be about 0.5 Torr to about 22 Torr. In some embodiments, the chamber pressure during operation 104b is the same as the chamber pressure during operation 104a. In one example, argon gas is introduced at a flow rate of about 40000 sccm for about 2 seconds at a chamber pressure of about 22 Torr. In another example, nitrogen gas is introduced at a flow rate of about 10000 sccm for about 2 seconds at a chamber of about 22 Torr. The flow rate, duration, and chamber pressure may depend on the precursor used in operation 104a and the topography of the substrate where the protective layer is to be deposited. Operation 104b is performed without igniting a plasma. Operation 104b is performed in a plasma-free environment.

In some embodiments, operations 104a and 104b are performed in a plasma-free environment.

In some embodiments, plasma may be used. In some embodiments, plasma may be used to densify or modify the protective layer. During plasma exposure, one or more of the following gases may be used: inert gases, oxidizing gases, and nitrogen-containing gases. Such gases may be used to ignite the plasma, forming an inert gas plasma, oxidizing plasma or nitrogen-containing plasma. Inert gas plasmas may be used to densify the decomposed material. Example inert gases include hydrogen, helium, argon, and xenon. Inert plasmas may be used to smoothen the surface of the decomposed film, which can allow thickness to be even across the surface. In various embodiments, inert gas plasma is performed for every about 1 nm of film deposited on a substrate surface. Oxidizing gases may be used to oxidize the decomposed material, such as to form silicon oxide. Example oxidizing gases include oxygen, nitrous oxide, carbon dioxide, ozone, and peroxides. Nitrogen-containing gases may be used to form a nitride of the decomposed material, such as to form silicon nitride. Example nitrogen-containing gases include nitrogen gas and ammonia. In various embodiments, oxidizing or nitrogen-containing plasmas may be used for every about 5 nm or less of film deposited on a substrate surface. During exposure to an oxidizing plasma or nitrogen-containing plasma, one or more additional inert gases may also be used. In some embodiments, hydrogen may also be used. Hydrogen may also be used to assist with ashing carbon-containing components of the decomposed film, such as if an organosilane is used during decomposition and the decomposed film has substantial carbon content. In some embodiments, an oxygen-free, or nitrogen-free, or oxygen- and -nitrogen-free plasma may be used. In some embodiments, the plasma is only ignited in a processing environment having inert gas. In some embodiments, a mixture of gases are used when the plasma is ignited.

In operation 104c, it is determined whether the protective layer has been deposited to an adequate thickness. The thickness desired for the protective layer depends on a number of factors, including but not limited to the silicon-containing precursor used, the structure or topography of the substrate provided in operation 102, the function that the protective layer will have when depositing silicon nitride in operation 108, the thickness of the silicon nitride to be deposited in operation 108, the process conditions that will be used in operation 108, and whether some thickness of the protective layer is desired after depositing silicon nitride in operation 108. In one non-limiting example, if some thickness is desired after depositing silicon nitride in operation 108, a thicker protective layer may be deposited. However, it is also possible to deposit a thin protective layer and still maintain a desired thickness after depositing silicon nitride by toggling the process conditions used in operation 108. If the protective layer is not yet deposited to an adequate thickness, then operations 104a and 104b may be repeated until a desired thickness is achieved.

In some embodiments, the protective layer is deposited to a thickness of at least about 10 Å, or at least about 13 Å, or about 10 Å to about 50 Å, or bout 10 Å to about 20 Å, or about 12 Å to about 15 Å. In some embodiments, if the process conditions used in operation 108 involve high temperature or high power plasma or other harsher process conditions, the thickness of the protective layer may be increased to accommodate the later exposure to plasma to deposit SiN, so that the underlying low-k dielectric is sufficiently protected. One non-limiting example of high temperature is a temperature of greater than 650° C. for a high power plasma process having a plasma power of at least about 6000 kW or at least about 10000 kW per station. In contrast, silicon nitride can be deposited at a temperature as low as about 100° C. with about 3000 kW to about 6000 kW RF power.

The protective layer may, in some embodiments, have properties that enable it to withstand certain wet etching conditions. For example, the wet etch rate of the protective layer in 100:1 dilute hydrofluoric acid may be about 0.06 Å/min or lower.

In certain embodiments, purging may be performed between any or all operations, such as after decomposition but before inert plasma exposure, or after inert plasma exposure and before oxidizing or nitrogen-containing plasma exposure, or after oxidizing or nitrogen-containing plasma exposure and before repeating any of the above operations, or any number of these operations or all of these operations. Purging may be optional. In some embodiments, purging is not performed between operations 104a and 104b.

Certain disclosed embodiments may allow faster deposition due to a higher deposition rate. For example, a cycle of precursor decomposition may form a film that is about 2 Å to about 3 Å thick. Depending on the precursor used, the deposition rate may vary.

Certain disclosed embodiments also can be used to form films having various dopants, which may be introduced during any operation or by using particular deposition precursors in vapor phase in a plasma-free environment. Dopants include but are not limited to carbon (C), nitrogen (N), boron (B), and phosphorous (P). Such dopants may be incorporated by exposing the substrate to one or more of the following gases: C₃H₆, and ammonia (NH₃). Certain disclosed embodiments may form films having silicon oxide, silicon nitride, silicon carbide, silicon oxycarbide, silicon oxynitride, doped variants thereof, or combinations thereof.

Returning to FIG. 1A, in operation 106, the process chamber may be optionally purged. Purging may be performed using any of gases, flow rates, temperatures, pressures, and other process conditions described above with respect to operation 104b without evacuating the chamber. Purging the chamber may involve flowing a purge gas or a sweep gas, which may be a carrier gas used in other operations or may be a different gas. In some embodiments, purging may involve evacuating the chamber. Example purge gases include argon, nitrogen, hydrogen, and helium. In some embodiments, the purge gas is flow for a duration of about 1000 sccm to about 40000 sccm at a chamber pressure of about 0.5 Torr or about 22 Torr.

In some embodiments, operation 106 may include one or more evacuation subphases for evacuating the process chamber. Alternatively, it will be appreciated that operation 106 may be omitted in some embodiments. Operation 106 may have any suitable duration, such as between about 0 seconds and about 60 seconds, or about 0.1 second to about 10 seconds. In some embodiments, increasing a flow rate of one or more purge gases may decrease the duration of operation 106. For example, a purge gas flow rate may be adjusted according to various reactant thermodynamic characteristics and/or geometric characteristics of the process chamber and/or process chamber plumbing for modifying the duration of operation 106. In one non-limiting example, the duration of a purge phase may be adjusted by modulating purge gas flow rate. This may reduce deposition cycle time, which may improve substrate throughput.

In operation 108, silicon nitride is deposited over the protective layer and over the low-k dielectric material. During operation 108, at least a portion of the protective layer may be converted to SiN. During operation 108, at least a portion of the top layers of the protective layer may be converted to SiN. Deposition in operation 108 may involve igniting a plasma.

FIG. 1C provides an example of one method for depositing silicon nitride in a plasma environment in operation 108. While FIG. 1C shows one example it will be understood that other deposition techniques that may at least partially convert part of the protective layer to silicon nitride while depositing silicon nitride may also be used and the protective layer may still have the advantages described herein.

FIG. 1C shows operation 108 can be performed using operations 108a, 108b, 108c, 108d, and 108e. Operations 108b and operation 108d are optional. Operations 108a and 108c may constitute one deposition cycle. Operations 108a and 108c may constitute one ALD cycle.

In operation 108a, a silicon-containing precursor may be introduced to the process chamber. The silicon-containing precursor may be any precursor described above with respect to operation 104a and described elsewhere herein. In some embodiments, the silicon-containing precursor contains or is the same as the silicon-containing precursor used in operation 104a. In some embodiments, the silicon-containing precursor does not contain or is different from the silicon-containing precursor used in operation 104a.

In some embodiments, the silicon-containing precursor may be flowed at a flow rate of about 100 sccm to about 2000 sccm for a single-wafer chamber. The silicon-containing precursor may be flowed with an inert push gas, such as nitrogen gas or argon gas or a mixture of nitrogen and argon gas. The flow rate of the inert push gas may be about 300 sccm to about 1500 sccm for a single-wafer chamber. Operation 108a may be performed for a duration of about 0.1 second to about 10 seconds. During operation 108a, the process chamber may have a chamber pressure of about 1 Torr to about 25 Torr. In some embodiments, additional nitrogen gas may be introduced with the silicon-containing precursor and/or the inert push gas for dilution, for pressure stability, or both. The additional nitrogen gas may be flowed at a flow rate of about 500 sccm to about 2000 sccm for a single-wafer chamber. In one example, DIPAS is introduced to a chamber housing the substrate having the protective layer thereon at a flow rate of about 200 sccm for about 2 seconds at a chamber pressure of about 18 Torr in a plasma-free environment.

In operation 108b, the process chamber is optionally purged. Purging may be performed in accordance with any of the chemistries or process conditions described above with respect to operation 106 of FIG. 1A. In some embodiments, the process chamber is purged using a mixture of nitrogen gas and argon gas. Operation 108b may be performed for a duration of about 0.1 second to about 10 seconds. The chamber pressure during operation 108b may be about 0.5 Torr to about 25 Torr. In some embodiments, the chamber pressure during operation 108b is the same as during operation 108a.

In one example, the nitrogen gas is flowed at a flow rate of about 20 slm and the argon gas is flowed at a flow rate of about 20 slm for a single-wafer chamber for about 1 second at a chamber pressure of about 18 Torr with no plasma. Purging may involve stopping flow of the silicon-containing precursor and introducing the purge gas(es).

Returning to FIG. 1C, in operation 108c, the substrate is exposed to a nitrogen-containing plasma which converts at least some adsorbed silicon-containing precursor to silicon nitride and reacts with at least a portion of the protective layer to convert the portion to silicon nitride. When the protective layer is exposed to the plasma in operation 108c, at least a portion of the protective layer is converted to silicon nitride. At the same time, additional silicon nitride may also grow over the protective layer. Prolonged exposure to nitrogen-containing plasma or repeated operations or specific process conditions may convert more protective layer to silicon nitride to a particular penetrating depth of the protective layer. Exposure to the nitrogen-containing plasma may also eventually convert all of the protective layer to silicon nitride. The resulting substrate has silicon nitride over the dielectric material where it is indistinguishable where the protective layer was previously deposited or formed. The quality of the silicon nitride formed from both the plasma deposition and the conversion of the protective layer may also be indistinguishable.

Operation 108c may involve stopped purging and/or stopping the flow of the purge gas and starting introduction of the nitrogen-containing plasma. In some embodiments, for an in-situ plasma, operation 108c involves stopping purging or introduction of a purge gas, and flowing nitrogen-containing gas into the process chamber and igniting the plasma. In some embodiments, for remote plasma, operation 108c involves stopping purging or introduction of a purge gas, and introducing nitrogen-containing plasma species to the process chamber from a remote plasma generator.

In various embodiments, the nitrogen-containing plasma is generated by igniting a nitrogen-containing gas, such as nitrogen (N₂) gas. A nitrogen-containing gas may be flowed at a flow rate of about 1000 sccm to about 5000 sccm for a single-wafer chamber. In some embodiments, the nitrogen-containing plasma is generated by igniting a mixture of nitrogen-containing gas and hydrogen-containing gas, such as a mixture of nitrogen and hydrogen, a mixture of nitrogen and ammonia, a mixture of nitrogen, hydrogen, and ammonia, and the like. In one example, a mixture of nitrogen gas and hydrogen gas may have a flow rate of nitrogen gas of about 20 slm and a flow rate of hydrogen gas of bout 10 sccm to about 1000 sccm. An inert gas which may be used as a push gas or carrier gas may also be flowed. The inert gas may be argon in some embodiments. The inert gas may be flowed at a flow rate of about 10 slm to about 40 slm. Operation 108c may be performed for a duration of about 1 second to about 30 seconds. The chamber pressure during operation 108c may be about 15 Torr to about 25 Torr. In some embodiments, a higher pressure, such as at least about 10 Torr, may be used to deposit conformal SiN. The plasma may be generated using a plasma power of about 500 W to about 6000 kW. In some embodiments, the chamber pressure during operation 108c is the same as during any one or more of operations 108a and 108b.

In one example, during operation 108c, after stopping the purging, nitrogen gas is flowed at a flow rate of about 2000 sccm, argon is flowed at a flow rate of about 18 slm, and plasma is ignited using a plasma power of about 2 kW for a duration of about 5 seconds in a chamber having a chamber pressure of about 18 Torr.

In some embodiments, operation 108c involves multiple operations, including exposing the substrate to a nitrogen-containing gas, optionally purging, and exposing the substrate to a nitrogen-containing plasma. This may be referred to as a “hybrid” deposition. In such embodiments, one cycle of depositing SiN in operation 108 involves introducing a silicon-containing precursor in operation 108a, optionally purging in operation 108b, introducing a nitrogen-containing gas without igniting a plasma or in a plasma-free environment, optionally purging, introducing a nitrogen-containing gas, and optionally purging in operation 108d.

Where a hybrid deposition process is used for depositing SiN, the nitrogen-containing gas introduced without igniting a plasma or the nitrogen-containing gas introduced in a plasma-free environment may be ammonia (NH₃) gas. In some embodiments, NH₃ is introduced at a flow rate of about 1000 sccm to about 4500 sccm for a single-wafer chamber. In some embodiments, NH₃ is introduced with one or more of a dilution gas, such as nitrogen, or argon, or both. In some embodiments, during exposure to the nitrogen-containing gas without igniting a plasma, nitrogen is flowed at a flow rate of about 1000 sccm to about 5000 sccm for a single-wafer chamber. Argon may be flowed at a flow rate of about 10 slm to about 40 slm for a single-wafer chamber. Exposure to the nitrogen-containing gas without igniting a plasma may be performed for a duration of about 1 second to about 30 seconds. Exposure to the nitrogen-containing gas without igniting a plasma may be performed at a chamber pressure of about 15 Torr to about 25 Torr. In one example, NH₃ is introduced at a flow rate of about 4.5 slm, and a mixture of nitrogen and argon gas is introduced at a flow rate of about 10 slm. Introduction to the nitrogen-containing gas without igniting a plasma may convert some silicon-containing precursor adsorbed onto a surface of the substrate in operation 108a to form silicon nitride.

After exposing to the nitrogen-containing gas in a plasma-free environment, an optional purging operation may be performed, which may be performed in accordance with any of the chemistries or process conditions described above with respect to operation 106 of FIG. 1A. In some embodiments, purging involves flowing nitrogen gas at a flow rate of about 20 slm. In some embodiments, purging involves flowing argon at a flow rate of about 20 slm. In some embodiments, purging is performed for a duration of about 0.1 second to about 10 seconds. In some embodiments, purging is performed at a chamber pressure of about 0.5 Torr to about 25 Torr.

In a hybrid SiN deposition process, a plasma operation may be performed using a nitrogen-containing plasma. In some embodiments, this operation includes flowing a nitrogen-containing gas, such as nitrogen gas. The nitrogen-containing gas may be flowed at a flow rate of about 1000 sccm to about 5000 sccm. In some embodiments, multiple nitrogen-containing gases may be flowed. For example, in addition to nitrogen gas, ammonia may also be flowed. In some embodiments, in addition to nitrogen gas, hydrogen gas may also be flowed. In some embodiments, in addition to nitrogen gas, both ammonia and hydrogen gas may also be flowed.

Inert gases may also be flowed during this operation. For example, argon may be flowed. The inert gas may be flowed at a flow rate of about 10 slm to about 40 slm. The plasma operation may be performed for a duration of about 1 second to about 30 seconds. The chamber pressure during plasma exposure may be about 15 Torr to about 25 Torr. The plasma may be generated using a plasma power of about 500 W to about 6000 kW.

In one example, during the plasma operation, about 2000 sccm of nitrogen is flowed with about 125 sccm of ammonia, in about 18 slm of argon gas, where nitrogen and ammonia are ignited using a plasma having a power of about 2 kW for a duration of about 5 seconds at a chamber pressure of about 18 Torr.

For this plasma operation and for any other plasma environment that may be used in operation 108, such as in operation 108c, in various embodiments, the plasma may be an inductively coupled plasma or a capacitively coupled plasma. An inductively coupled plasma may be set at a plasma between about 500 W to about 6000 kW. In some embodiments, a bias may be applied between about 0V and about 1000V. In some embodiments, a bias is not applied.

Without being bound by a particular theory, it is believed that exposure of the protective layer to the nitrogen-containing plasma at least partially converts portions of the protective layer to SiN. For example, the plasma may provide sufficient energy to cleave certain bonds in the decomposed silicon-containing precursor in the protective layer while incorporating nitrogen, leaving SiN on the substrate surface. While conversion occurs, some additional SiN may also be deposited onto the surface of the substrate by converting silicon-containing precursor that adsorbed to the substrate surface such as any silicon-containing precursor adsorbed onto the surface of the protective layer.

In operation 108d, the process chamber is optionally purged. Purging may be performed in accordance with any of the chemistries or process conditions described above with respect to operation 106 of FIG. 1A. In some embodiments, purging is performed using the same process conditions as during operation 108b. Purging can be performed using a nitrogen gas, argon gas, or a mixture of both, or any other inert gas. In some embodiments, nitrogen gas is flowed at a flow rate of about 20 slm. Argon may be flowed at a flow rate of about 20 slm. Each inert gas flowed during purging may be flowed using a flow rate of about 20 slm. Purging may be performed for a duration of about 0.1 second to about 10 seconds. Purging may be performed for the same duration as that which was performed in operation 108b. The chamber pressure during operation 108d may be about 0.5 Torr to about 25 Torr. In some embodiments, the chamber pressure during operation 108d is the same as during any one or more of operations 108a, 108b, and 108c.

In operation 108e, it is determined whether the film is deposited to an adequate thickness. If not, operations 108a and 108c may be repeated. In some embodiments, operations 108a, 108b, 108c, and 108d may be repeated in cycles. One cycle may constitute at least performing operations 108a and 108c once. One cycle may constitute performing each of operations 108a, 108b, 108c, and 108d once. In some embodiments, operations may be repeated to convert all or at least about 90% of the protective layer to silicon nitride. In some embodiments, operations may be repeated to leave a few Angstroms of thickness of protective layer between the dielectric material and the silicon nitride. The protective layer may have robust wet etch rate and depending on its application, may serve as an extra protective layer over the dielectric to bolster the overall stack.

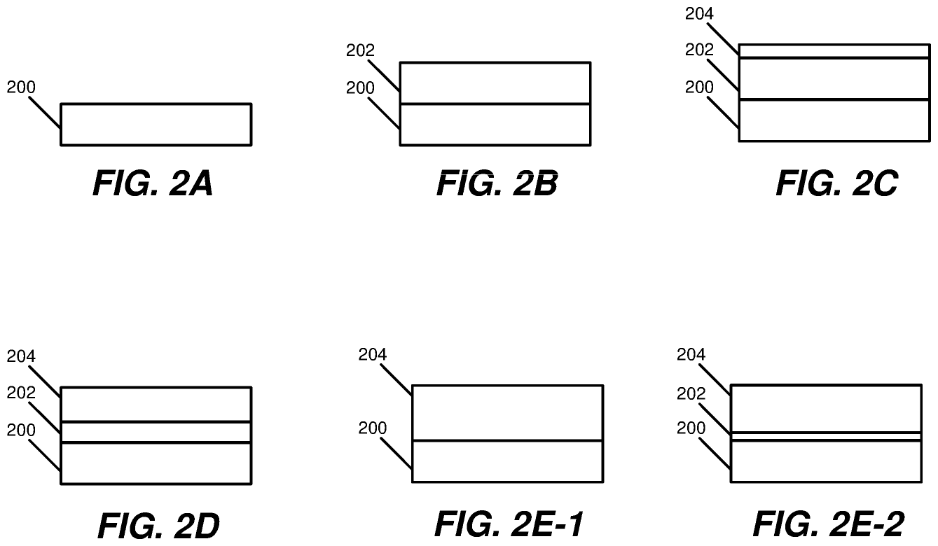

An example of leaving a portion of the protective layer between the low-k dielectric or SiOC layer and the SiN layer is provided in FIG. 2E-2 which is further described below.

FIG. 2A shows a low-k dielectric silicon oxycarbide substrate 200. This example substrate may correspond to a substrate that may be provided in operation 102 of FIG. 1A. FIG. 2B shows a protective layer 202 deposited thereon. The protective layer 202 may be deposited using operation 104 in FIG. 1A, or an example process having operations 104a and 104b and optionally 104c of FIG. 1B. FIG. 2C shows the beginning of growth of silicon nitride 204 over the protective layer 202. This may correspond to operation 108 of FIG. 1A and optionally operations 108a and 108c of FIG. 1, or operations 108a, 108b, 108c, 108d, and 108e of FIG. 1C. As deposition occurs and exposure to nitrogen-containing plasma occurs, in FIG. 2D, more over the protective layer 202 is converted to silicon nitride while silicon nitride 204 is also further deposited over the protective layer 202. In some embodiments, in FIG. 2E-1, all of the protective layer is converted to silicon nitride 204 resulting in silicon nitride 204 being adjacent to and in direct contact with low-k dielectric silicon oxycarbide 200. Alternatively, in some embodiments, in FIG. 2E-2, after FIG. 2D, a portion of the protective layer 202 is left unconverted between silicon nitride 204 and low-k dielectric silicon oxycarbide 200 such that protective layer 202 is in contact with and/or sandwiched between silicon nitride 204 and low-k dielectric silicon oxycarbide 200.

### Apparatus

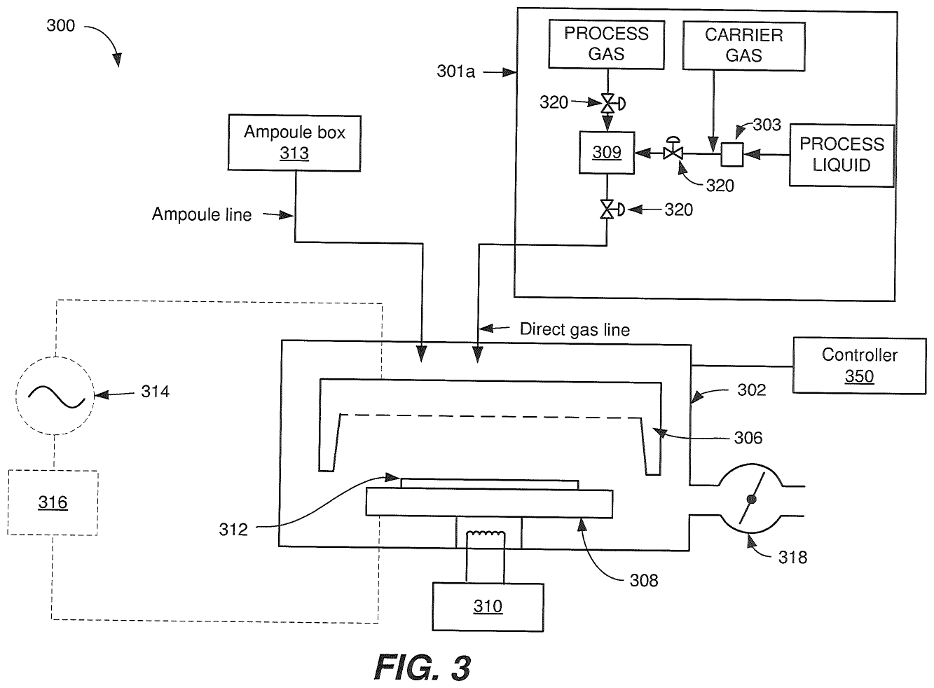

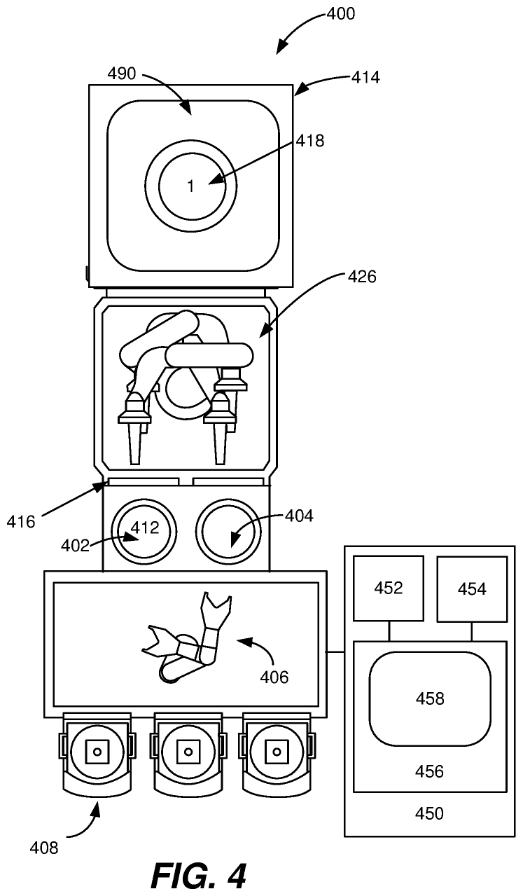

FIG. 3 depicts a schematic illustration of an embodiment of an atomic layer deposition (ALD) process station 300 having a process chamber body 302. In various embodiments, a single process station 300 is implemented in a tool such as shown in FIG. 4. In some embodiments, a plurality of ALD process stations 300 may be included in a low pressure process tool environment. For example, FIG. 3 depicts an embodiment of a multi-station processing tool 300. In some embodiments, one or more hardware parameters of ALD process station 300 including those discussed in detail below may be adjusted programmatically by one or more computer controllers 350.

ALD process station 300 fluidly communicates with reactant delivery system 301a for delivering process gases to a showerhead 306. Reactant delivery system 301a includes a mixing vessel 304 for blending and/or conditioning process gases, such as a silicon-containing precursor gas, or nitrogen-containing gas, for delivery to showerhead 306. One or more mixing vessel inlet valves 320 may control introduction of process gases to mixing vessel 304. One or more valves 305 may control introduction of gases to the showerhead 306.

As an example, the embodiment of FIG. 3 includes a vaporization point 303 for vaporizing liquid reactant to be supplied to the mixing vessel 304. In some embodiments, vaporization point 303 may be a heated vaporizer. The saturated reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve purging and/or evacuating the delivery piping to remove residual reactant. However, purging the delivery piping may increase process station cycle time, degrading process station throughput. Thus, in some embodiments, delivery piping downstream of vaporization point 303 may be heat traced. In some examples, mixing vessel (not shown) may also be heat traced. In one non-limiting example, piping downstream of vaporization point 303 has an increasing temperature profile extending from approximately 40° C. to approximately 55° C. or from about 60° C. to about 65° C. at mixing vessel.

In some embodiments, liquid precursor or liquid reactant may be vaporized at a liquid injector. For example, a liquid injector may inject pulses of a liquid reactant into a carrier gas stream upstream of the mixing vessel. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 303. In one scenario, a liquid injector may be mounted directly to mixing vessel. In another scenario, a liquid injector may be mounted directly to showerhead 306.

In some embodiments, a liquid flow controller (LFC) upstream of vaporization point 303 may be provided for controlling a mass flow of liquid for vaporization and delivery to ALD process station 300. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

Showerhead 306 distributes process gases toward substrate 312. In the embodiment shown in FIG. 3, the substrate 312 is located beneath showerhead 306 and is shown resting on a pedestal 308. Showerhead 306 may have any suitable shape, and may have any suitable number and arrangement of ports for distributing process gases to substrate 312.

In some embodiments, pedestal 308 may be raised or lowered to expose substrate 312 to a volume between the substrate 312 and the showerhead 306. It will be appreciated that, in some embodiments, pedestal height may be adjusted programmatically by a suitable computer controller 350.

In another scenario, adjusting a height of pedestal 308 may allow a plasma density to be varied during plasma activation in the process in embodiments where a plasma is ignited. At the conclusion of the process phase, pedestal 308 may be lowered during another substrate transfer phase to allow removal of substrate 312 from pedestal 308.

In some embodiments, pedestal 308 may be temperature controlled via heater 310. In some embodiments, the pedestal 308 may be heated to a temperature of about 25° C. to about 800° C., or about 200° C. to about 700° C., during deposition of silicon oxide films as described in disclosed embodiments. In some embodiments, the pedestal is set at a temperature of about 45° C. to about 800° C., or about 500° C. to about 700° C. In some embodiments, the same pedestal 308 is used for multiple operations in accordance with certain disclosed embodiments.

Further, in some embodiments, pressure control for ALD process station 300 may be provided by butterfly valve 318. As shown in the embodiment of FIG. 3, butterfly valve 318 throttles a vacuum provided by a downstream vacuum pump (not shown). However, in some embodiments, pressure control of ALD process station 300 may also be adjusted by varying a flow rate of one or more gases introduced to the ALD process station 300.

In some embodiments, a position of showerhead 306 may be adjusted relative to pedestal 308 to vary a volume between the substrate 312 and the showerhead 306. Further, it will be appreciated that a vertical position of pedestal 308 and/or showerhead 306 may be varied by any suitable mechanism within the scope of the present disclosure. In some embodiments, pedestal 308 may include a rotational axis for rotating an orientation of substrate 312. It will be appreciated that, in some embodiments, one or more of these example adjustments may be performed programmatically by one or more suitable computer controllers 350.

In some embodiments where plasma may be used as discussed above, showerhead 306 and pedestal 308 electrically communicate with a radio frequency (RF) power supply 314 and matching network 316 for powering a plasma. For example, plasma may be used for treating a silicon oxide surface prior to depositing silicon nitride. In some embodiments, the plasma energy may be controlled by controlling one or more of a process station pressure, a gas concentration, an RF source power, an RF source frequency, and a plasma power pulse timing. For example, RF power supply 314 and matching network 316 may be operated at any suitable power to form a plasma having a desired composition of radical species. Examples of suitable powers are about 150 W to about 10000 W or about 500 W to about 6000 kW for a single-station chamber. For a 3-station chamber, the plasma power may include four generators each powered up to about 10000 W, for a total of about 30000 W. For annealing a silicon oxide film, the substrate may be exposed to a nitrogen-containing gas, or a mixture of nitrogen-containing gases and optional inert gases while igniting a plasma using the RF power supply 314 and matching network 316.

In some embodiments, the substrate may be exposed to nitrogen-containing gas while igniting a plasma to anneal silicon oxide using plasma powers such as between about 500 W and about 10000 W per surface area of a 300 mm wafer. The plasma may be generated remotely (such as in a remote plasma generator) or directly in a chamber housing the substrate (i.e. in situ). RF power supply 314 may provide RF power of any suitable frequency. In some embodiments, RF power supply 314 may be configured to control high- and low-frequency RF power sources independently of one another. Example low-frequency RF frequencies may include, but are not limited to, frequencies between 0 kHz and 500 kHz. Example high-frequency RF frequencies may include, but are not limited to, frequencies between 1.8 MHz and 3.45 GHz, or greater than about 13.56 MHz, or greater than 27 MHz, or greater than 30 MHz, or greater than 60 MHz. It will be appreciated that any suitable parameters may be modulated discretely or continuously to provide plasma energy for the surface reactions.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, instructions for a controller 350 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for setting a flow rate of a silicon-containing precursor gas, instructions for setting a flow rate of a carrier gas (such as argon), and time delay instructions for the first recipe phase. A second recipe phase may include modulating or stopping a flow rate of an inert and/or a reactant gas, instructions for optionally heating, instructions for setting a flow rate of a carrier gas (such as argon), and time delay instructions for a second recipe phase. A third, subsequent recipe phase may include instructions for modulating or stopping a flow rate of an inert and/or a reactant gas, and instructions for modulating a flow rate of a second silicon-containing precursor and time delay instructions for the third recipe phase. A fourth recipe phase may include instructions for modulating or stopping a flow rate of an inert and/or a reactant gas, instructions for modulating the flow rate of a carrier or purge gas, and time delay instructions for the fourth recipe phase. A fifth, subsequent recipe phase may include instructions for setting a flow rate of a nitrogen-containing gas, instructions for igniting a plasma, and instructions for modulating a flow rate of a carrier or purge gas and time delay instructions for the fifth recipe phase. A sixth recipe phase may include instructions for modulating or stopping a flow rate of an inert and/or a reactant gas, instructions for modulating the flow rate of a carrier or purge gas, and time delay instructions for the sixth recipe phase. It will be appreciated that these recipe phases may be further subdivided and/or iterated in any suitable way within the scope of the disclosed embodiments. In some embodiments, the controller 350 may include any of the features described below with respect to system controller 450 of FIG. 4 and system controller 350 of FIG. 3.

A process station may be included in a single-station chamber or single-chamber tool such as shown in FIG. 4. FIG. 4 depicts an example processing apparatus according to disclosed embodiments. Tool 400 includes a processing chamber 414 which includes a processing station 490 may process a wafer. The processing chamber 414 is configured to deposit silicon oxide, deposit silicon nitride, anneal substrates using thermal or plasma anneals, and the like.

Tool 400 also includes a wafer transfer unit configured to transport wafers within the tool 400. Additional features of tool 400 will be discussed in greater detail below, and various features are discussed here with respect to some of the described techniques. In the depicted illustration, the wafer transfer unit includes a first robotic arm unit 426 in a first wafer transfer module and a second robotic arm unit 406 in a second wafer transfer module that may be considered an equipment front end module (EFEM) configured to received containers for wafers, such as a front opening unified module (FOUP) 408. The first robotic arm unit 426 is configured to transport a wafer between the processing chamber 414 and the second robotic arm unit via module 404 which may hold multiple wafers such as shown in module 402 with substrate 412. The second robotic arm unit 406 is configured to transport the wafer between a FOUP and module 404, or from module 402 to FOUP. After a wafer has been prepared in the module 404, the wafer transfer unit is able to transfer the wafer to first processing chamber 414 for deposition and optional anneal in situ.

Similar to above, the first wafer transfer module may a vacuum transfer module (VTM). Airlock or module 404, also known as a loadlock, is shown and may be individually optimized to perform various fabrication processes. The tool 400 also includes a FOUP 408 that is configured to lower the pressure of the tool 400 to a vacuum or low pressure, e.g., between about 1 mTorr and about 10 Torr, and maintain the tool 400 at this pressure. This includes maintaining the processing chamber 414, and the first wafer transfer module at the vacuum or low pressure. The second wafer transfer module may be at a different pressure, such as atmospheric. As the wafer is transferred throughout the tool 400, it is therefore maintained at the vacuum or low pressure.

In a further example, a substrate is placed in one of the FOUPs 408 and the second robot arm unit 406, or front-end robot, transfers the substrate from the FOUP 418 to an aligner, which allows the substrate to be properly centered before it is etched, or deposited upon, or otherwise processed. After being aligned, the substrate is moved by the second robot arm unit 406 into the airlock module 404. Because airlock modules have the ability to match the environment between an ATM and a VTM, the substrate is able to move between the two pressure environments without being damaged. From the airlock module 404, the substrate is moved by the first robot arm unit 426 through the first wafer transfer module, or VTM, and into the processing chamber 414. In order to achieve this substrate movement, the first robot arm unit 426 uses end effectors on each of its arms.

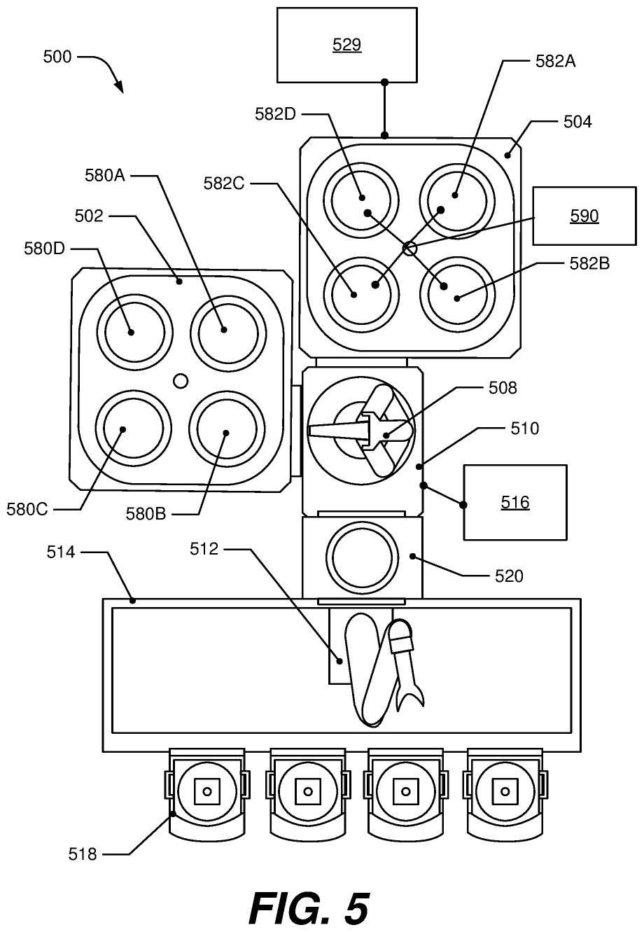

FIG. 4 also depicts an embodiment of a system controller 450 employed to control process conditions and hardware states of process tool 400. System controller 450 may include one or more memory devices 456, one or more mass storage devices 454, and one or more processors 452. Processor 452 may include a CPU or computer, analog and/or digital input/output connections, stepper motor controller boards, etc. In some embodiments, system controller 450 includes machine-readable instructions for performing operations such as those described above with respect to FIG. 5 and below with respect to FIG. 5.

As described above, one or more process stations may be included in a multi-station processing tool. FIG. 5 depicts an example processing apparatus according to disclosed embodiments. Tool 500 includes a first processing chamber 502 and a second processing chamber 504. The first processing chamber 502 includes a plurality of processing stations, four stations 580A-D, that each may process a wafer. The first processing chamber 502 is configured to perform plasma treatment operations on the wafers. The second processing chamber 504 is configured to perform deposition on the wafer and may be considered a deposition chamber. The second processing chamber 504 also includes a plurality of processing stations, four stations 582A-D, that each may process a wafer. The first and second processing chambers 502 and 504 may be considered multi-station processing chambers.

Tool 500 also includes a wafer transfer unit configured to transport one or more wafers within the tool 500. Additional features of tool 500 will be discussed in greater detail below, and various features are discussed here with respect to some of the described techniques. In the depicted illustration, the wafer transfer unit includes a first robotic arm unit 508 in a first wafer transfer module 510 and a second robotic arm unit 512 in a second wafer transfer module 514 that may be considered an equipment front end module (EFEM) configured to received containers for wafers, such as a front opening unified module (FOUP) 516. The first robotic arm unit 508 is configured to transport a wafer between the first processing chamber 502 and the second processing chamber 504, and between the second the second robotic arm unit 512. The second robotic arm unit 512 is configured to transport the wafer between a FOUP and the first robotic arm unit 508. After a wafer has been treated in the first processing chamber 502, the wafer transfer unit is able to transfer the wafer from the first processing chamber 502, to the second processing chamber 504 where one or more layers of encapsulation material may be deposited on one or more wafers.

Similar to above, the first wafer transfer module 510 may a vacuum transfer module (VTM). Airlock 520, also known as a loadlock or transfer module, is shown and may be individually optimized to perform various fabrication processes. The tool 500 also includes a FOUP 516 that is configured to lower the pressure of the tool 500 to a vacuum or low pressure, e.g., between about 1 mTorr and about 10 Torr, and maintain the tool 500 at this pressure. This includes maintaining the first and second processing chambers 502 and 504, and the first wafer transfer module 510 at the vacuum or low pressure. The second wafer transfer module 514 may be at a different pressure, such as atmospheric. As the wafer is transferred throughout the tool 500, it is therefore maintained at the vacuum or low pressure. For example, as the wafer is transferred from the first processing chamber 502, into the first wafer transfer module 510, and to the second processing chamber 504, the wafer is maintained at the vacuum or low pressure and not exposed to atmospheric pressure.

In a further example, a substrate is placed in one of the FOUPs 518 and the second robot arm unit 512, or front-end robot, transfers the substrate from the FOUP 518 to an aligner, which allows the substrate to be properly centered before it is etched, or deposited upon, or otherwise processed. After being aligned, the substrate is moved by the second robot arm unit 512 into the airlock 520. Because airlock modules have the ability to match the environment between an ATM and a VTM, the substrate is able to move between the two pressure environments without being damaged. From the airlock 520, the substrate is moved by the first robot arm unit 508 through the first wafer transfer module 510, or VTM 510, and into the first processing chamber 502. In order to achieve this substrate movement, the first robot arm unit 508 uses end effectors on each of its arms.

FIG. 5 also depicts an embodiment of a system controller 529 employed to control process conditions and hardware states of tool 500. System controller 529 may include one or more memory devices (not shown), one or more mass storage devices (not shown), and one or more processors (not shown). Processors may include a CPU or computer, analog, and/or digital input/output connections, stepper motor controller boards, etc.

In some embodiments, system controller 529 controls all of the activities of tool 500. System controller 529 executes system control software stored in mass storage device, loaded into memory device, and executed on processor. Alternatively, the control logic may be hard coded in the system controller 529. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software may include instructions for controlling the timing, mixture of gases, gas flow rates, chamber and/or station pressure, chamber and/or station temperature, wafer temperature, target power levels, RF power levels, substrate pedestal, chuck and/or susceptor position, and parameters of a particular process performed by tool 500. System control software may be configured in any suitable way. For example, various process tool component subroutines or control objects may be written to control operation of the process tool components used to carry out various process tool processes. System control software may be coded in any suitable computer readable programming language.

In some embodiments, system control software may include input/output control (IOC) sequencing instructions for controlling the various parameters described above. Other computer software and/or programs stored on mass storage device and/or memory device associated with system controller 529 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal and to control the spacing between the substrate and other parts of tool 500.

A process gas control program may include code for controlling gas composition (e.g., silicon-containing precursor gases, nitrogen-containing gases, carrier gases, inert gases, and/or purge gases as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium or nitrogen) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 529. The user interface may include a display screen, graphical software displays of the apparatus and/or process conditions, and user input devices such as pointing devices, keyboards, touch screens, microphones, etc.

In some embodiments, parameters adjusted by system controller 529 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 529 from various process tool sensors. The signals for controlling the process may be output on the analog and digital output connections of tool 500. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 529 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various embodiments described herein.

The system controller 529 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 529.

In some implementations, the system controller 529 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 529, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 529 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 529 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 529, in some implementations, may be a part of or coupled to a computer that is integrated with, coupled to the system, otherwise networked to the system, or a combination thereof. For example, the system controller 529 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 529 receives instructions in the form of data, which specify parameters for each of the processing steps to be performed during one or more operations. It should be understood that the parameters may be specific to the type of process to be performed and the type of tool that the system controller 529 is configured to interface with or control. Thus as described above, the system controller 529 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the system controller 529 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

An appropriate apparatus for performing the methods disclosed herein is further discussed and described in U.S. patents application Ser. Nos. 13/084,399 (now U.S. Pat. No. 8,728,956), filed Apr. 11, 2011, and titled “PLASMA ACTIVATED CONFORMAL FILM DEPOSITION”; and Ser. No. 13/084,305, filed Apr. 11, 2011, and titled “SILICON NITRIDE FILMS AND METHODS,” each of which is incorporated herein in its entireties.

The apparatus/process described herein may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### Experimental

### Experiment 1

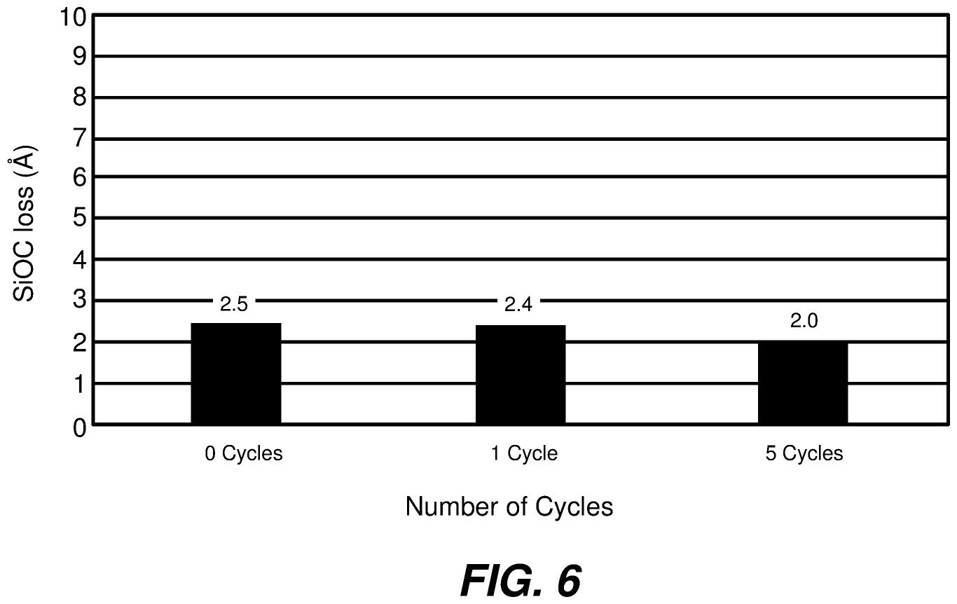

Substrates having silicon oxynitride deposited thereon were exposed to 0 cycles of depositing a protective layer by decomposition, 1 cycle of depositing a protective layer by decomposition, and 5 cycles of depositing a protective layer by decomposition; all three substrates were wet etched for 30 minutes in dilute hydrofluoric acid having a 100:1 dilution ratio and the amount of silicon oxynitride loss was measured. The results are shown in FIG. 6, which shows that the silicon oxynitride loss across all substrates were comparable so silicon oxynitride is not damaged by deposition of the protective layer by decomposition.

### Experiment 2

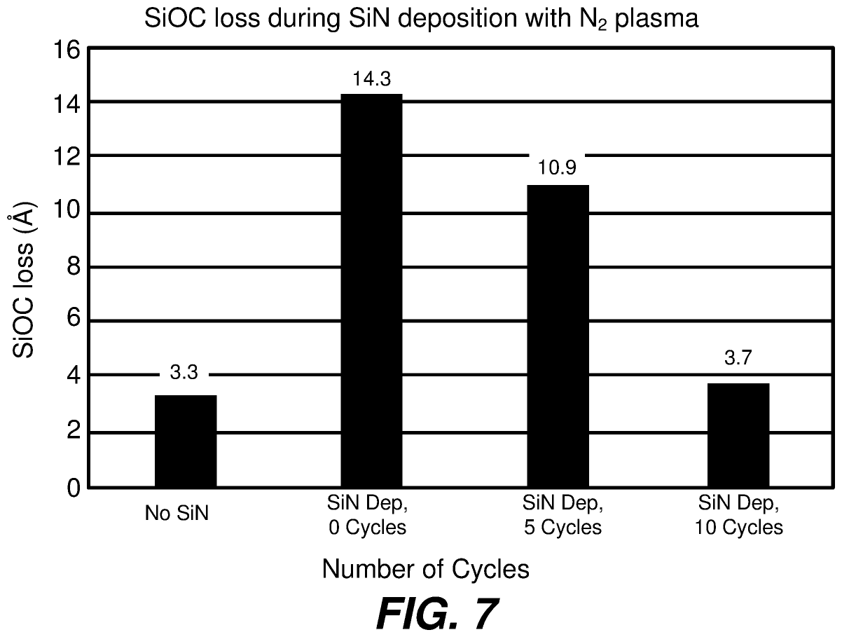

Substrates having silicon oxynitride deposited thereon were exposed to 0 cycles of depositing a protective layer by decomposition, 1 cycle of depositing a protective layer by decomposition then silicon nitride deposition using nitrogen plasma, 5 cycles of depositing a protective layer by decomposition then silicon nitride deposition using nitrogen plasma, and 10 cycles of depositing a protective layer by decomposition then silicon nitride deposition using nitrogen plasma. All four substrates were wet etched for 30 minutes in dilute hydrofluoric acid having a 100:1 dilution ratio and the amount of silicon oxynitride loss was measured. The results are shown in FIG. 7, which shows silicon oxynitride loss without any protective layer being 14.3 Å, while a thin protective layer reduces silicon oxynitride loss to 10.9, and a thicker protective layer reduces the silicon oxynitride loss to 3.7 Å showing less than 0.5 Å of damage overall. These results suggest the silicon oxynitride damage can be reduced by increasing the protective layer thickness.

### Experiment 3

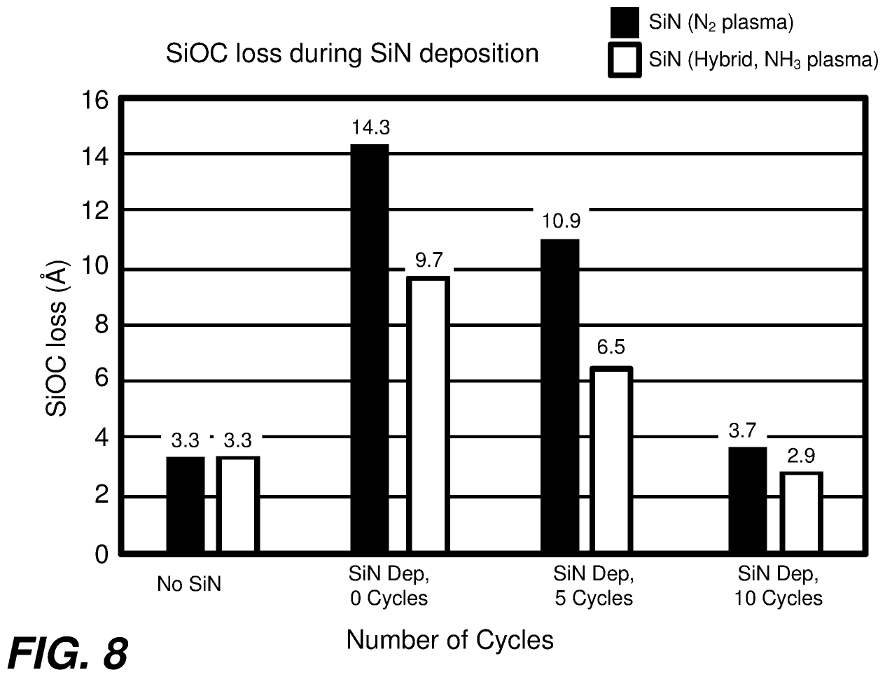

Substrates having silicon oxynitride deposited thereon were exposed to 0 cycles of depositing a protective layer by decomposition, 1 cycle of depositing a protective layer by decomposition then silicon nitride deposition using nitrogen plasma, 1 cycle of depositing a protective layer by decomposition then cyclic silicon nitride deposition using thermal ammonia conversion and nitrogen/ammonia plasma, 5 cycles of depositing a protective layer by decomposition then silicon nitride deposition using nitrogen plasma, 5 cycles of depositing a protective layer by decomposition then cyclic silicon nitride deposition using thermal ammonia conversion and nitrogen/ammonia plasma, 10 cycles of depositing a protective layer by decomposition then silicon nitride deposition using nitrogen plasma, and 10 cycles of depositing a protective layer by decomposition then cyclic silicon nitride deposition using thermal ammonia conversion and nitrogen/ammonia plasma. All 7 substrates were wet etched for 30 minutes in dilute hydrofluoric acid having a 100:1 dilution ratio and the amount of silicon oxynitride loss was measured. The results are shown in FIG. 8, which shows silicon oxynitride damage can be reduced by increasing the thickness of the protective layer regardless of the type of plasma used for silicon nitride deposition as compared between these two deposition techniques.

### DEFINITIONS AND PRECURSORS

### Definitions

The term “acyl,” or “alkanoyl,” as used interchangeably herein, represents groups of 1, 2, 3, 4, 5, 6, 7, 8 or more carbon atoms of a straight, branched, cyclic configuration, saturated, unsaturated and aromatic, and combinations thereof, or hydrogen, attached to the parent molecular group through a carbonyl group, as defined herein. This group is exemplified by formyl (—C(O)H), acetyl(Ac or —C(O) Me), propionyl, isobutyryl, butanoyl, and the like. In some embodiments, the acyl or alkanoyl group is —C(O)—R, in which R is hydrogen, an aliphatic group, or an aromatic group, as defined herein.

By “alkanoyloxy” is meant an alkanoyl group, as defined herein, attached to the parent molecular group through an oxy group, as defined herein. This group is exemplified by acetoxy (—OAc or —OC(O) Me). In some embodiments, the alkanoyloxy group is —OC(O)—R, in which R is hydrogen, an aliphatic group, or an aromatic group, as defined herein.

By “aliphatic” is meant a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well. An aliphatic group is unsubstituted or substituted, e.g., by a functional group described herein. For example, the aliphatic group can be substituted with one or more substitution groups, as described herein for alkyl.

By “aliphatic-carbonyl” is meant an aliphatic group that is or can be coupled to a compound disclosed herein, wherein the aliphatic group is or becomes coupled through a carbonyl group (—C(O)—). In some embodiments, the aliphatic-carbonyl group is —C(O)—R, in which R is an optionally substituted aliphatic group, as defined herein.

By “aliphatic-carbonyloxy” is meant an aliphatic group that is or can be coupled to a compound disclosed herein, wherein the aliphatic group is or becomes coupled through a carbonyloxy group (—OC(O)—). In some embodiments, the aliphatic-carbonyloxy group is —OC(O)—R, in which R is an optionally substituted aliphatic group, as defined herein.

By “aliphatic-oxy” is meant an aliphatic group that is or can be coupled to a compound disclosed herein, wherein the aliphatic group is or becomes coupled through an oxy group (—C(O)—). In some embodiments, the aliphatic-oxy group is —O—R, in which R is an optionally substituted aliphatic group, as defined herein.

By “aliphatic-oxycarbonyl” is meant an aliphatic group that is or can be coupled to a compound disclosed herein, wherein the aliphatic group is or becomes coupled through an oxycarbonyl group (—C(O)O—). In some embodiments, the aliphatic-oxycarbonyl group is —C(O)O—R, in which R is an optionally substituted aliphatic group, as defined herein.

By “alkyl-aryl,” “alkenyl-aryl,” and “alkynyl-aryl” is meant an alkyl, alkenyl, or alkynyl group, respectively and as defined herein, that is or can be coupled (or attached) to the parent molecular group through an aryl group, as defined herein. The alkyl-aryl, alkenyl-aryl, and/or alkynyl-aryl group can be substituted or unsubstituted. For example, the alkyl-aryl, alkenyl-aryl, and/or alkynyl-aryl group can be substituted with one or more substitution groups, as described herein for alkyl and/or aryl. Exemplary unsubstituted alkyl-aryl groups are of from 7 to 16 carbons (C₇₋₁₆ alkyl-aryl), as well as those having an alkyl group with 1 to 6 carbons and an aryl group with 4 to 18 carbons (i.e., C₁₋₆ alkyl-C₄₋₁₈ aryl). Exemplary unsubstituted alkenyl-aryl groups are of from 7 to 16 carbons (C₇₋₁₆ alkenyl-aryl), as well as those having an alkenyl group with 2 to 6 carbons and an aryl group with 4 to 18 carbons (i.e., C₂₋₆ alkenyl-C₄₋₁₈ aryl). Exemplary unsubstituted alkynyl-aryl groups are of from 7 to 16 carbons (C₇₋₁₆ alkynyl-aryl), as well as those having an alkynyl group with 2 to 6 carbons and an aryl group with 4 to 18 carbons (i.e., C₂₋₆ alkynyl-C₄₋₁₈ aryl). In some embodiments, the alkyl-aryl group is—L—R, in which L is an aryl group or an arylene group, as defined herein, and R is an alkyl group, as defined herein. In some embodiments, the alkenyl-aryl group is—L—R, in which L is an aryl group or an arylene group, as defined herein, and R is an alkenyl group, as defined herein. In some embodiments, the alkynyl-aryl group is —L—R, in which L is an aryl group or an arylene group, as defined herein, and R is an alkynyl group, as defined herein.

By “alkenyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon double bond, wherein the unsaturated monovalent hydrocarbon can be derived from removing one hydrogen atom from one carbon atom of a parent alkene. An alkenyl group can be branched, straight-chain, cyclic (e.g., cycloalkenyl), cis, or trans (e.g., E or Z). An exemplary alkenyl includes an optionally substituted C₂₋₂₄ alkyl group having one or more double bonds. The alkenyl group can be monovalent or multivalent (e.g., bivalent) by removing one or more hydrogens to form appropriate attachment to the parent molecular group or appropriate attachment between the parent molecular group and another substitution. The alkenyl group can also be substituted or unsubstituted. For example, the alkenyl group can be substituted with one or more substitution groups, as described herein for alkyl. Non-limiting alkenyl groups include allyl(All), vinyl(Vi), 1-butenyl, 2-butenyl, and the like.

By “alkoxy” is meant-OR, where R is an optionally substituted aliphatic group, as described herein. Exemplary alkoxy groups include, but are not limited to, methoxy, ethoxy, n-propoxy, isopropoxy, n-butoxy, t-butoxy, sec-butoxy, n-pentoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkoxyalkyl” is meant an alkyl group, as defined herein, which is substituted with an alkoxy group, as defined herein. Exemplary unsubstituted alkoxyalkyl groups include between 2 to 12 carbons (C₂₋₁₂ alkoxyalkyl), as well as those having an alkyl group with 1 to 6 carbons and an alkoxy group with 1 to 6 carbons (i.e., C₁₋₆ alkoxy-C₁₋₆ alkyl). In some embodiments, the alkoxyalkyl group is —L—O—R, in which each of L and R is, independently, an alkyl group, as defined herein.

By “alkoxycarbonyl” is meant —C(O)—OR, where R is an optionally substituted aliphatic group, as described herein. In particular embodiments, the alkoxycarbonyl group is —C(O)—OAk, in which Ak is an alkyl group, as defined herein. The alkoxycarbonyl group can be substituted or unsubstituted. For example, the alkoxycarbonyl group can be substituted with one or more substitution groups, as described herein for alkyl. Exemplary unsubstituted alkoxycarbonyl groups include C₂₋₃, C₂₋₆, C₂₋₇, C₂₋₁₂, C₂₋₁₆, C₂₋₁₈, C₂₋₂₀, or C₂₋₂₄ alkoxycarbonyl groups.

By “alkyl” is meant a saturated monovalent hydrocarbon having at least one carbon atom to 50 carbon atoms (C₁₋₅₀), such as one to 25 carbon atoms (C₁₋₂₅), or one to ten carbon atoms (C₁₋₁₀), wherein the saturated monovalent hydrocarbon can be derived from removing one hydrogen atom from one carbon atom of a parent compound (e.g., alkane). An alkyl group can be branched, straight-chain, or cyclic (e.g., cycloalkyl). An exemplary alkyl includes a branched or unbranched saturated hydrocarbon group of 1 to 24 carbon atoms, such as methyl (Me), ethyl (Et), n-propyl(nPr), iso-propyl(iPr), n-butyl(nBu), iso-butyl(iBu), sec-butyl(sBu), tert-butyl(tBu), pentyl(Pe), n-pentyl(nPe), isopentyl(iPe), s-pentyl(sPe), neopentyl(neoPe), tert-pentyl(tPe), hexyl(Hx), heptyl(Hp), octyl(Oc), nonyl(Nn), decyl(De), dodecyl, tetradecyl, hexadecyl, eicosyl, tetracosyl, and the like. The alkyl group can also be substituted or unsubstituted. The alkyl group can be monovalent or multivalent (e.g., bivalent) by removing one or more hydrogens to form appropriate attachment to the parent molecular group or appropriate attachment between the parent molecular group and another substitution. For example, the alkyl group can be substituted with one, two, three or, in the case of alkyl groups of two carbons or more, four substituents independently selected from the group consisting of: (1) C₁₋₆ alkoxy (e.g., —O—R, in which R is C₁₋₆ alkyl); (2) C₁₋₆ alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4)amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, can form a heterocyclyl group, as defined herein); (5) aryl; (6) arylalkoxy (e.g., —O—L—R, in which L is alkyl and R is aryl); (7) aryloyl (e.g., —C(O)—R, in which R is aryl); (8) azido (e.g., —N₃); (9) cyano (e.g., —CN); (10) aldehyde (e.g., —C(O)H); (11) C₃₋₈ cycloalkyl; (12) halo; (13) heterocyclyl (e.g., as defined herein, such as a 5-, 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17) N-protected amino; (18) nitro (e.g., —NO₂); (19) oxo (e.g., ═O); (20) C₁₋₆ thioalkyl (e.g., —S—R, in which R is alkyl); (21) thiol (e.g., —SH); (22)—CO₂R¹, where R¹ is selected from the group consisting of (a) hydrogen, (b) C₁₋₆ alkyl, (c) C₄₋₁₈ aryl, and (d) C₄₋₁₈ aryl-C₁₋₆ alkyl (e.g., —L—R, in which L is C₁₋₆ alkyl and R is C₄₋₁₈ aryl); (23)—C(O) NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., —L—R, in which Lis C₁₋₆ alkyl and R is C₄₋₁₈ aryl); (24)—SO₂R¹, where R¹ is selected from the group consisting of (a) C₁₋₆ alkyl, (b) C₄₋₁₈ aryl, and (c) C₄₋₁₈ aryl-C₁₋₆ alkyl (e.g., —L—R, in which L is C₁₋₆ alkyl and R is C₄₋₁₈ aryl); (25)—SO₂NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., —L—R, in which L is C₁₋₆ alkyl and R is C₄₋₁₈ aryl); and (26)—NR¹R², where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., —L—R, in which Lis C₁₋₆ alkyl and R is C₄₋₁₈ aryl), (h) C₃₋₈ cycloalkyl, and (i) C₃₋₈ cycloalkyl-C₁₋₆ alkyl (e.g., —L—R, in which L is C₁₋₆ alkyl and R is C₃₋₈ cycloalkyl), wherein in one embodiment no two groups are bound to the nitrogen atom through a carbonyl group or a sulfonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

By “alkylene,” “alkenylene,” or “alkynylene” is meant a multivalent (e.g., bivalent) form of an alkyl, alkenyl, or alkynyl group, respectively, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. In other embodiments, the alkylene group is a C₂₋₃, C₂₋₆, C₂₋₁₂, C₂₋₁₆, C₂₋₁₈, C₂₋₂₀, or C₂₋₂₄ alkenylene or alkynylene group. The alkylene, alkenylene, or alkynylene group can be branched or unbranched. The alkylene, alkenylene, or alkynylene group can also be substituted or unsubstituted. For example, the alkylene, alkenylene, or alkynylene group can be substituted with one or more substitution groups, as described herein for alkyl.

By “alkylsulfinyl” is meant an alkyl group, as defined herein, attached to the parent molecular group through an —S(O)— group. In some embodiments, the unsubstituted alkylsulfinyl group is a C₁₋₆ or C₁₋₁₂ alkylsulfinyl group. In other embodiments, the alkylsulfinyl group is —S(O)—R, in which R is an alkyl group, as defined herein.

By “alkylsulfinylalkyl” is meant an alkyl group, as defined herein, substituted by an alkylsulfinyl group. In some embodiments, the unsubstituted alkylsulfinylalkyl group is a C₂₋₁₂ or C₂₋₂₄ alkylsulfinylalkyl group (e.g., C₁₋₆ alkylsulfinyl-C₁₋₆ alkyl or C₁₋₁₂ alkylsulfinyl-C₁₋₁₂ alkyl). In other embodiments, the alkylsulfinylalkyl group is —L—S(O)—R, in which each of L and R is, independently, an alkyl group, as defined herein.

By “alkylsulfonyl” is meant an alkyl group, as defined herein, attached to the parent molecular group through an —SO₂-group. In some embodiments, the unsubstituted alkylsulfonyl group is a C₁₋₆ or C₁₋₁₂ alkylsulfonyl group. In other embodiments, the alkylsulfonyl group is —SO₂—R, where R is an optionally substituted alkyl (e.g., as described herein, including optionally substituted C₁₋₁₂ alkyl, haloalkyl, or perfluoroalkyl).

By “alkylsulfonylalkyl” is meant an alkyl group, as defined herein, substituted by an alkylsulfonyl group. In some embodiments, the unsubstituted alkylsulfonylalkyl group is a C₂₋₁₂ or C₂₋₂₄ alkylsulfonylalkyl group (e.g., C₁₋₆ alkylsulfonyl-C₁₋₆ alkyl or C₁₋₁₂ alkylsulfonyl-C₁₋₁₂ alkyl). In other embodiments, the alkylsulfonylalkyl group is —L—SO₂—R, in which each of L and R is, independently, an alkyl group, as defined herein.

By “alkynyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon triple bond, wherein the unsaturated monovalent hydrocarbon can be derived from removing one hydrogen atom from one carbon atom of a parent alkyne. An alkynyl group can be branched, straight-chain, or cyclic (e.g., cycloalkynyl). An exemplary alkynyl includes an optionally substituted C₂₋₂₄ alkyl group having one or more triple bonds. The alkynyl group can be cyclic or acyclic and is exemplified by ethynyl, 1-propynyl, and the like. The alkynyl group can be monovalent or multivalent (e.g., bivalent) by removing one or more hydrogens to form appropriate attachment to the parent molecular group or appropriate attachment between the parent molecular group and another substitution. The alkynyl group can also be substituted or unsubstituted. For example, the alkynyl group can be substituted with one or more substitution groups, as described herein for alkyl.

By “ambient temperature” is meant a temperature ranging from 16° C. to 26° C., such as from 19° C. to 25° C. or from 20° C. to 25° C.

By “amide” is mean —C(O) NR¹R² or —NHCOR¹, where each of R¹ and R² is, independently, selected from hydrogen, aliphatic, heteroaliphatic, aromatic, as defined herein, or any combination thereof, or where R¹ and R², taken together with the nitrogen atom to which each are attached, can form a heterocyclyl group, as defined herein.

By “amino” is meant-NR¹R², where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy. In particular embodiments, R¹ and R² can be taken together, with the nitrogen atom to which each is attached, to form an optionally substituted heterocyclyl.

By “aminoalkyl” is meant an alkyl group, as defined herein, substituted by an amino group, as defined herein. In some embodiments, the aminoalkyl group is —L—NR¹R², in which L is an alkyl group, as defined herein, and each of R¹ and R² is, independently, selected from hydrogen, aliphatic, heteroaliphatic, or aromatic, as defined herein, or any combination thereof; or R¹ and R², taken together with the nitrogen atom to which each are attached, can form a heterocyclyl group, as defined herein. In other embodiments, the aminoalkyl group is —L—C(NR¹R²)(R³)—R⁴, in which L is a covalent bond or an alkyl group, as defined herein; each of R¹ and R² is, independently, selected from hydrogen, aliphatic, heteroaliphatic, or aromatic, as defined herein, or any combination thereof; or R¹ and R², taken together with the nitrogen atom to which each are attached, can form a heterocyclyl group, as defined herein; and each of R³ and R⁴ is, independently, H or alkyl, as defined herein.

By “aminooxy” is meant an oxy group, as defined herein, substituted by an amino group, as defined herein. In some embodiments, the aminooxy group is —O—NR¹R², in which each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy.

By “aromatic” is meant a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane π-electrons corresponds to the Huckel rule (4n+2). The point of attachment to the parent structure typically is through an aromatic portion of the condensed ring system. An aromatic group is unsubstituted or substituted, e.g., by a functional group described herein. For example, the aromatic group can be substituted with one or more substitution groups, as described herein for alkyl and/or aryl.

By “aromatic-carbonyl” is meant an aromatic group that is or can be coupled to a compound disclosed herein, wherein the aromatic group is or becomes coupled through a carbonyl group (—C(O)—). In some embodiments, the aromatic-carbonyl group is —C(O)—R, in which R is an optionally substituted aromatic group, as defined herein.

By “aromatic-carbonyloxy” is meant an aromatic group that is or can be coupled to a compound disclosed herein, wherein the aromatic group is or becomes coupled through a carbonyloxy group (—OC(O)—). In some embodiments, the aromatic-carbonyloxy group is —OC(O)—R, in which R is an optionally substituted aromatic group, as defined herein.

By “aromatic-oxy” is meant an aromatic group that is or can be coupled to a compound disclosed herein, wherein the aromatic group is or becomes coupled through an oxy group (—O—). In some embodiments, the aromatic-oxy group is —O—R, in which R is an optionally substituted aromatic group, as defined herein.

By “aromatic-oxycarbonyl” is meant an aromatic group that is or can be coupled to a compound disclosed herein, wherein the aromatic group is or becomes coupled through an oxycarbonyl group (—C(O)O—). In some embodiments, the aromatic-carbonyl group is —C(O)O—R, in which R is an optionally substituted aromatic group, as defined herein.

By “aryl” is meant an aromatic carbocyclic group comprising at least five carbon atoms to 15 carbon atoms (C₅₋₁₅), such as five to ten carbon atoms (C₅₋₁₀), having a single ring or multiple condensed rings, which condensed rings can or may not be aromatic provided that the point of attachment to a remaining position of the compounds disclosed herein is through an atom of the aromatic carbocyclic group. Aryl groups may be substituted with one or more groups other than hydrogen, such as aliphatic, heteroaliphatic, aromatic, other functional groups, or any combination thereof. Exemplary aryl groups include, but are not limited to, benzyl, naphthalene, phenyl, biphenyl, phenoxybenzene, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents independently selected from the group consisting of: (1) C₁₋₆ alkanoyl (e.g., —C(O)—R, in which R is C₁₋₆ alkyl); (2) C₁₋₆ alkyl; (3) C₁₋₆ alkoxy (e.g., —O—R, in which R is C₁₋₆ alkyl); (4) C₁₋₆ alkoxy-C₁₋₆ alkyl (e.g., —L—O—R, in which each of L and R is, independently, C₁₋₆ alkyl); (5) C₁₋₆ alkylsulfinyl (e.g., —S(O)—R, in which R is C₁₋₆ alkyl); (6) C₁₋₆ alkylsulfinyl-C₁₋₆ alkyl (e.g., —L—S(O)—R, in which each of L and R is, independently, C₁₋₆ alkyl); (7) C₁₋₆ alkylsulfonyl (e.g., —SO₂—R, in which R is C₁₋₆ alkyl); (8) C₁₋₆ alkylsulfonyl-C₁₋₆ alkyl (e.g., —L—SO₂—R, in which each of L and R is, independently, C₁₋₆ alkyl); (9) aryl; (10)amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein); (11) C₁₋₆ aminoalkyl (e.g., —L¹—NR¹R² or —L²—C(NR¹R²)(R³)—R⁴, in which L¹ is C₁₋₆ alkyl; L² is a covalent bond or C₁₋₆ alkyl; each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein; and each of R³ and R⁴ is, independently, H or C₁₋₆ alkyl); (12) heteroaryl; (13) C₄₋₁₈ aryl-C₁₋₆ alkyl (e.g., —L—R, in which L is C₁₋₆ alkyl and R is C₄₋₁₈ aryl); (14) aryloyl (e.g., —C(O)—R, in which R is aryl); (15) azido (e.g., —N₃); (16) cyano (e.g., —CN); (17) C₁₋₆ azidoalkyl (e.g., —L-N₃, in which L is C₁₋₆ alkyl); (18) aldehyde (e.g., —C(O)H); (19) aldehyde-C₁₋₆ alkyl (e.g., —L—C(O)H, in which L is C₁₋₆ alkyl); (20) C₃₋₈ cycloalkyl; (21) C₃₋₈ cycloalkyl-C₁₋₆ alkyl (e.g., —L—R, in which Lis C₁₋₆ alkyl and R is C₃₋₈ cycloalkyl); (22) halo; (23) C₁₋₆ haloalkyl (e.g., —L¹-X or -L²—C(X)(R¹)—R², in which L¹ is C₁₋₆ alkyl; L² is a covalent bond or C₁₋₆ alkyl; X is fluoro, bromo, chloro, or iodo; and each of R¹ and R² is, independently, H or C₁₋₆ alkyl); (24) heterocyclyl (e.g., as defined herein, such as a 5-, 6- or 7-membered ring containing one, two, three, or four non-carbon heteroatoms); (25) heterocyclyloxy (e.g., —O—R, in which R is heterocyclyl, as defined herein); (26) heterocyclyloyl (e.g., —C(O)—R, in which R is heterocyclyl, as defined herein); (27) hydroxyl (—OH); (28) C₁₋₆ hydroxyalkyl (e.g., —L¹—OH or —L²—C(OH)(R¹)—R², in which L¹ is C₁₋₆ alkyl; L² is a covalent bond or alkyl; and each of R¹ and R² is, independently, H or C₁₋₆ alkyl, as defined herein); (29) nitro; (30) C₁₋₆ nitroalkyl (e.g., —L¹-NO or —L²—C(NO)(R¹)—R², in which L¹ is C₁₋₆ alkyl; L² is a covalent bond or alkyl; and each of R¹ and R² is, independently, H or C₁₋₆ alkyl, as defined herein); (31) N-protected amino; (32) N-protected amino-C₁₋₆ alkyl; (33) oxo (e.g., ═O); (34) C₁₋₆ thioalkyl (e.g., —S—R, in which R is C₁₋₆ alkyl); (35) thio-C₁₋₆ alkoxy-C₁₋₆ alkyl (e.g., —L—S—R, in which each of L and R is, independently, C₁₋₆ alkyl); (36)—(CH₂),CO₂R¹, where r is an integer of from zero to four, and R¹ is selected from the group consisting of (a) hydrogen, (b) C₁₋₆ alkyl, (c) C₄₋₁₈ aryl, and (d) C₄₋₁₈ aryl-C₁₋₆ alkyl (e.g., —L—R, in which L is C₁₋₆ alkyl and R is C₄₋₁₈ aryl); (37)—(CH₂),CONR¹R², where r is an integer of from zero to four and where each R¹ and R² is independently selected from the group consisting of (a) hydrogen, (b) C₁₋₆ alkyl, (c) C₄₋₁₈ aryl, and (d) C₄₋₁₈ aryl-C₁₋₆ alkyl (e.g., —L—R, in which L is C₁₋₆ alkyl and R is C₄₋₁₈ aryl); (38)—(CH₂),SO₂R¹, where r is an integer of from zero to four and where R¹ is selected from the group consisting of (a) C₁₋₆ alkyl, (b) C₄₋₁₈ aryl, and (c) C₄₋₁₈ aryl-C₁₋₆ alkyl (e.g., —L—R, in which L is C₁₋₆ alkyl and R is C₄₋₁₈ aryl); (39)—(CH₂)ᵣSO₂NR¹R², where r is an integer of from zero to four and where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., —L—R, in which L is C₁₋₆ alkyl and R is C₄₋₁₈ aryl); (40)—(CH₂).NR¹R², where r is an integer of from zero to four and where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., —L—R, in which L is C₁₋₆ alkyl and R is C₄₋₁₈ aryl), (h) C₃₋₈ cycloalkyl, and (i) C₃₋₈ cycloalkyl-C₁₋₆ alkyl (e.g., —L—R, in which L is C₁₋₆ alkyl and R is C₃₋₈ cycloalkyl), wherein in one embodiment no two groups are bound to the nitrogen atom through a carbonyl group or a sulfonyl group; (41) thiol (e.g., —SH); (42) perfluoroalkyl (e.g., —(CF₂),CF₃, in which n is an integer from 0 to 10); (43) perfluoroalkoxy (e.g., —O—(CF₂),CF₃, in which n is an integer from 0 to 10); (44) aryloxy (e.g., —O—R, in which R is aryl); (45) cycloalkoxy (e.g., —O—R, in which R is cycloalkyl); (46) cycloalkylalkoxy (e.g., —O—L—R, in which L is alkyl and R is cycloalkyl); and (47) arylalkoxy (e.g., —O—L—R, in which L is alkyl and R is aryl). In particular embodiments, an unsubstituted aryl group is a C₄₋₁₈, C₄₋₁₄, C₄₋₁₂, C₄₋₁₀, C₆₋₁₈, C₆₋₁₄, C₆₋₁₂, or C₆₋₁₀ aryl group.

By “aryl-alkyl,” “aryl-alkenyl,” and “aryl-alkynyl” is meant an aryl group, as defined herein, that is or can be coupled (or attached) to the parent molecular group through an alkyl, alkenyl, or alkynyl group, respectively, as defined herein. The aryl-alkyl, aryl-alkenyl, and/or aryl-alkynyl group can be substituted or unsubstituted. For example, the aryl-alkyl, aryl-alkenyl, and/or aryl-alkynyl group can be substituted with one or more substitution groups, as described herein for aryl and/or alkyl. Exemplary unsubstituted aryl-alkyl groups are of from 7 to 16 carbons (C₇₋₁₆ aryl-alkyl), as well as those having an aryl group with 4 to 18 carbons and an alkyl group with 1 to 6 carbons (i.e., C₄₋₁₈ aryl-C₁₋₆ alkyl). Exemplary unsubstituted aryl-alkenyl groups are of from 7 to 16 carbons (C₇₋₁₆ aryl-alkenyl), as well as those having an aryl group with 4 to 18 carbons and an alkenyl group with 2 to 6 carbons (i.e., C₄₋₁₈ aryl-C₂₋₆ alkenyl). Exemplary unsubstituted aryl-alkynyl groups are of from 7 to 16 carbons (C₇₋₁₆ aryl-alkynyl), as well as those having an aryl group with 4 to 18 carbons and an alkynyl group with 2 to 6 carbons (i.e., C₄₋₁₈ aryl-C₂₋₆ alkynyl). In some embodiments, the aryl-alkyl group is —L—R, in which L is an alkyl group or an alkylene group, as defined herein, and R is an aryl group, as defined herein. In some embodiments, the aryl-alkenyl group is —L—R, in which L is an alkenyl group or an alkenylene group, as defined herein, and R is an aryl group, as defined herein. In some embodiments, the aryl-alkynyl group is —L—R, in which L is an alkynyl group or an alkynylene group, as defined herein, and R is an aryl group, as defined herein.

By “arylene” is meant a multivalent (e.g., bivalent) form of an aryl group, as described herein. Exemplary arylene groups include phenylene, naphthylene, biphenylene, triphenylene, diphenyl ether, acenaphthenylene, anthrylene, or phenanthrylene. In some embodiments, the arylene group is a C₄₋₁₈, C₄₋₁₄, C₄₋₁₂, C₄₋₁₀, C₆₋₁₈, C₆₋₁₄, C₆₋₁₂, or C₆₋₁₀ arylene group. The arylene group can be branched or unbranched. The arylene group can also be substituted or unsubstituted. For example, the arylene group can be substituted with one or more substitution groups, as described herein for aryl.

By “arylalkoxy” is meant an aryl-alkyl group, as defined herein, attached to the parent molecular group through an oxygen atom. In some embodiments, the arylalkoxy group is —O—L—R, in which L is an alkyl group, as defined herein, and R is an aryl group, as defined herein.

By “aryloxy” is meant-OR, where R is an optionally substituted aryl group, as described herein. In some embodiments, an unsubstituted aryloxy group is a C₄₋₁₈ or C₆₋₁₈ aryloxy group. In other embodiments, R is an aryl group that is optionally substituted with alkyl, alkanoyl, amino, hydroxyl, and the like.

By “aryloxycarbonyl” is meant an aryloxy group, as defined herein, that is attached to the parent molecular group through a carbonyl group. In some embodiments, an unsubstituted aryloxycarbonyl group is a C₅₋₁₉ aryloxycarbonyl group. In other embodiments, the aryloxycarbonyl group is —C(O)O—R, in which R is an aryl group, as defined herein.

By “aryloyl” is meant an aryl group that is attached to the parent molecular group through a carbonyl group. In some embodiments, an unsubstituted aryloyl group is a C₇₋₁₁ aryloyl or C₅₋₁₉ aryloyl group. In other embodiments, the aryloyl group is —C(O)—R, in which R is an aryl group, as defined herein.

By “aryloyloxy” is meant an aryloyl group, as defined herein, that is attached to the parent molecular group through an oxy group. In some embodiments, an unsubstituted aryloyloxy group is a C₅₋₁₉ aryloyloxy group. In other embodiments, the aryloyloxy group is —OC(O)—R, in which R is an aryl group, as defined herein.

By “azido” is meant an —N₃ group.

By “azidoalkyl” is meant an azido group attached to the parent molecular group through an alkyl group, as defined herein. In some embodiments, the azidoalkyl group is —L—N₃, in which

L is an alkyl group, as defined herein.

By “azo” is meant an —N═N— group.

By “carbamoyl” is meant an amino group attached to the parent molecular group through a carbonyl group, as defined herein. In some embodiments, the carbamoyl is —C(O) NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein.

By “carbamoyloxy” is meant a carbamoyl group, as defined herein, attached to the parent molecular group through n oxy group, as defined herein. In some embodiments, the carbamoyl is —OC(O) NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein.

By “carbonimidoyl” is meant a —C(NR)— group. In some embodiments, R is selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof.

By “carbonyl” is meant a —C(O)— group, which can also be represented as >C═O.

By “carboxyl” is meant a —CO₂H group or an anion thereof.

By “catalyst” is meant a compound, usually present in small amounts relative to reactants, capable of catalyzing a synthetic reaction, as would be readily understood by a person of ordinary skill in the art. In some embodiments, catalysts may include transition metal coordination complex.

By “cyanato” is meant a —OCN group.

By “cyano” is meant a —CN group.

By “cycloaliphatic” is meant an aliphatic group, as defined herein, that is cyclic.

By “cycloalkoxy” is meant a cycloalkyl group, as defined herein, attached to the parent molecular group through an oxygen atom. In some embodiments, the cycloalkoxy group is —O—R, in which R is a cycloalkyl group, as defined herein.

By “cycloalkylalkoxy” is meant a —O—L—R group, in which L is an alkyl group or an alkylene group, as defined herein, and R is a cycloalkyl group, as defined herein.

By “cycloalkyl” is meant a monovalent saturated or unsaturated non-aromatic cyclic hydrocarbon group of from three to eight carbons, unless otherwise specified, and is exemplified by cyclopropyl, cyclobutyl, cyclopentyl, cyclohexyl, cycloheptyl, bicyclo[2.2.1.heptyl], and the like. The cycloalkyl group can also be substituted or unsubstituted. For example, the cycloalkyl group can be substituted with one or more groups including those described herein for alkyl. Further, cycloalkyl may include one or more double bonds and/or triple bonds.

By “cycloheteroaliphatic” is meant a heteroaliphatic group, as defined herein, that is cyclic.

By “disilanyl” is meant a group containing an Si—Si bond. In some embodiments, the disilanyl group is a —SiR^{S1}R^{S2}—SiR^{S3}R^{S4}R^{S5} or —SiR^{S1}R^{S2}—SiR^{S3}R^{S4}-group, in which each of R^{S1}, R^{S2}, R^{S3}, R^{S4}, and R^{S5} is, independently, H, optionally substituted aliphatic, optionally substituted heteroaliphatic, optionally substituted aromatic, optionally substituted heteroaromatic, or optionally substituted amino.

By “disulfide” is meant —SSR, where R is selected from hydrogen, aliphatic, heteroaliphatic, haloaliphatic, haloheteroaliphatic, aromatic, as defined herein, or any combination thereof.

By “electron-donating group” is meant a functional group capable of donating at least a portion of its electron density into the ring to which it is directly attached, such as by resonance.

By “electron-withdrawing group” is meant a functional group capable of accepting electron density from the ring to which it is directly attached, such as by inductive electron withdrawal.

By “halo” is meant F, Cl, Br, or I.

By “haloaliphatic” is meant an aliphatic group, as defined herein, in which one or more hydrogen atoms, such as one to 10 hydrogen atoms, independently is replaced with a halogen atom, such as fluoro, bromo, chloro, or iodo.

By “haloalkyl” is meant an alkyl group, as defined herein, where one or more hydrogen atoms, such as one to 10 hydrogen atoms, independently is replaced with a halogen atom, such as fluoro, bromo, chloro, or iodo. In an independent embodiment, haloalkyl can be a —CX₃ group, wherein each X independently can be selected from fluoro, bromo, chloro, or iodo. In some embodiments, the haloalkyl group is —L—X, in which L is an alkyl group, as defined herein, and X is fluoro, bromo, chloro, or iodo. In other embodiments, the haloalkyl group is —L—C(X)(R¹)—R², in which L is a covalent bond or an alkyl group, as defined herein; X is fluoro, bromo, chloro, or iodo; and each of R¹ and R² is, independently, H or alkyl, as defined herein.

By “haloheteroaliphatic” is meant a heteroaliphatic, as defined herein, in which one or more hydrogen atoms, such as one to 10 hydrogen atoms, independently is replaced with a halogen atom, such as fluoro, bromo, chloro, or iodo.

By “heteroaliphatic” is meant an aliphatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaliphatic group is unsubstituted or substituted, e.g., by a functional group described herein. For example, the heteroaliphatic group can be substituted with one or more substitution groups, as described herein for alkyl.

By “heteroaliphatic-carbonyl” is meant a heteroaliphatic group that is or can be coupled to a compound disclosed herein, wherein the heteroaliphatic group is or becomes coupled through a carbonyl group (—C(O)—). In some embodiments, the heteroaliphatic-carbonyl group is —C(O)—R, in which R is an optionally substituted heteroaliphatic group, as defined herein.

By “heteroaliphatic-carbonyloxy” is meant a heteroaliphatic group that is or can be coupled to a compound disclosed herein, wherein the heteroaliphatic group is or becomes coupled through a carbonyloxy group (—OC(O)—). In some embodiments, the heteroaliphatic-carbonyloxy group is —OC(O)—R, in which R is an optionally substituted heteroaliphatic group, as defined herein.

By “heteroaliphatic-oxy” is meant a heteroaliphatic group that is or can be coupled to a compound disclosed herein, wherein the heteroaliphatic group is or becomes coupled through an oxy group (—C(O)—). In some embodiments, the heteroaliphatic-oxy group is —O—R, in which R is an optionally substituted heteroaliphatic group, as defined herein.

By “heteroaliphatic-oxycarbonyl” is meant a heteroaliphatic group that is or can be coupled to a compound disclosed herein, wherein the heteroaliphatic group is or becomes coupled through an oxycarbonyl group (—C(O)O—). In some embodiments, the heteroaliphatic-oxycarbonyl group is —C(O)O—R, in which R is an optionally substituted heteroaliphatic group, as defined herein.

By “heteroalkyl,” “heteroalkenyl,” and “heteroalkynyl” is meant an alkyl, alkenyl, or alkynyl group (which can be branched, straight-chain, or cyclic), respectively, as defined herein, including at least one heteroatom to 20 heteroatoms, such as one to 15 heteroatoms, or one to 5 heteroatoms, which can be selected from, but not limited to, oxygen, nitrogen, sulfur, silicon, boron, selenium, phosphorous, and oxidized forms thereof within the group.

By “heteroalkylene,” “heteroalkenylene,” and “heteroalkynylene” is meant a multivalent (e.g., bivalent) form of a heteroalkyl, heteroalkenyl, or heteroalkynyl group, respectively, as described herein.

By “heteroaromatic” is meant an aromatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaromatic group is unsubstituted or substituted, e.g., by a functional group described herein. For example, the heteroaromatic group can be substituted with one or more substitution groups, as described herein for alkyl and/or aryl.

By “heteroaromatic-carbonyl” is meant a heteroaromatic group that is or can be coupled to a compound disclosed herein, wherein the heteroaromatic group is or becomes coupled through a carbonyl group (—C(O)—). In some embodiments, the heteroaromatic-carbonyl group is —C(O)—R, in which R is an optionally substituted heteroaromatic group, as defined herein.

By “heteroaromatic-carbonyloxy” is meant a heteroaromatic group that is or can be coupled to a compound disclosed herein, wherein the heteroaromatic group is or becomes coupled through a carbonyloxy group (—OC(O)—). In some embodiments, the heteroaromatic-carbonyloxy group is —OC(O)—R, in which R is an optionally substituted heteroaromatic group, as defined herein.

By “heteroaromatic-oxy” is meant a heteroaromatic group that is or can be coupled to a compound disclosed herein, wherein the heteroaromatic group is or becomes coupled through an oxy group (—O—). In some embodiments, the heteroaromatic-oxy group is —O—R, in which R is an optionally substituted heteroaromatic group, as defined herein.

By “heteroaromatic-oxycarbonyl” is meant a heteroaromatic group that is or can be coupled to a compound disclosed herein, wherein the heteroaromatic group is or becomes coupled through an oxycarbonyl group (—C(O)O—). In some embodiments, the heteroaromatic-carbonyl group is —C(O)O—R, in which R is an optionally substituted heteroaromatic group, as defined herein.

By “heteroaryl” is meant an aryl group including at least one heteroatom to six heteroatoms, such as one to four heteroatoms, which can be selected from, but not limited to, oxygen, nitrogen, sulfur, silicon, boron, selenium, phosphorous, and oxidized forms thereof within the ring. Such heteroaryl groups can have a single ring or multiple condensed rings, where the condensed rings may or may not be aromatic and/or contain a heteroatom, provided that the point of attachment is through an atom of the aromatic heteroaryl group. Heteroaryl groups may be substituted with one or more groups other than hydrogen, such as aliphatic, heteroaliphatic, aromatic, other functional groups, or any combination thereof. An exemplary heteroaryl includes a subset of heterocyclyl groups, as defined herein, which are aromatic, i.e., they contain 4n+2 pi electrons within the mono- or multicyclic ring system.

By “heteroarylene” is meant a multivalent (e.g., bivalent) form of a heteroaryl group, as described herein.

By “heteroatom” is meant an atom other than carbon, such as oxygen, nitrogen, sulfur, silicon, boron, selenium, or phosphorous. In particular disclosed embodiments, such as when valency constraints do not permit, a heteroatom does not include a halogen atom.

By “heterocyclyl” is meant a 5-, 6- or 7-membered ring, unless otherwise specified, containing one, two, three, or four non-carbon heteroatoms (e.g., independently selected from the group consisting of nitrogen, oxygen, phosphorous, sulfur, or halo). The 5-membered ring has zero to two double bonds and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include thiiranyl, thietanyl, tetrahydrothienyl, thianyl, thiepanyl, aziridinyl, azetidinyl, pyrrolidinyl, piperidinyl, azepanyl, pyrrolyl, pyrrolinyl, pyrazolyl, pyrazolinyl, pyrazolidinyl, imidazolyl, imidazolinyl, imidazolidinyl, pyridyl, homopiperidinyl, pyrazinyl, piperazinyl, pyrimidinyl, pyridazinyl, oxazolyl, oxazolidinyl, oxazolidonyl, isoxazolyl, isoxazolidiniyl, morpholinyl, thiomorpholinyl, thiazolyl, thiazolidinyl, isothiazolyl, isothiazolidinyl, indolyl, quinolinyl, isoquinolinyl, benzimidazolyl, benzothiazolyl, benzoxazolyl, furyl, thienyl, thiazolidinyl, isothiazolyl, isoindazoyl, triazolyl, tetrazolyl, oxadiazolyl, uricyl, thiadiazolyl, pyrimidyl, tetrahydrofuranyl, dihydrofuranyl, dihydrothienyl, dihydroindolyl, tetrahydroquinolyl, tetrahydroisoquinolyl, pyranyl, dihydropyranyl, tetrahydropyranyl, dithiazolyl, dioxanyl, dioxinyl, dithianyl, trithianyl, oxazinyl, thiazinyl, oxothiolanyl, triazinyl, benzofuranyl, benzothienyl, and the like.

By “heterocyclyloxy” is meant a heterocyclyl group, as defined herein, attached to the parent molecular group through an oxygen atom. In some embodiments, the heterocyclyloxy group is —O—R, in which R is a heterocyclyl group, as defined herein.

By “heterocyclyloyl” is meant a heterocyclyl group, as defined herein, attached to the parent molecular group through a carbonyl group. In some embodiments, the heterocyclyloyl group is —C(O)—R, in which R is a heterocyclyl group, as defined herein.

By “hydrazino” is meant-NR¹—NR²R³, where each of R¹, R², and R³ is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where a combination of R¹ and R² or a combination of R² and R³, taken together with the nitrogen atom to which each are attached, can form a heterocyclyl group, as defined herein. In some embodiments, each of R¹, R², or R³ is, independently, H, optionally substituted alkyl, optionally substituted aryl, optionally substituted alkyl-aryl, or optionally substituted aryl-alkyl. In particular embodiments, R² and R³ can be taken together, with the nitrogen atom to which each is attached, to form an optionally substituted heterocyclyl.

By “hydroxyl” is meant-OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like. In some embodiments, the hydroxyalkyl group is —L—OH, in which L is an alkyl group, as defined herein. In other embodiments, the hydroxyalkyl group is —L—C(OH)(R¹)—R², in which L is a covalent bond or an alkyl group, as defined herein, and each of R¹ and R² is, independently, H or alkyl, as defined herein.

By “imidoyl” is meant a moiety including a carbonimidoyl group. In some embodiments, the imidoyl group is C(NR¹) R², in which each of R¹ and R² is, independently, selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof. In other embodiments, the imidoyl group is —C(NR¹) H, —C(NR¹)R^{Ak}, or —C(NRN¹)R^{Ar}, in which R¹ is hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, or optionally substituted silyloxy; R^{Ak} is an optionally substituted alkyl or an optionally substituted aliphatic; and R^{Ar} is an optionally substituted aryl or an optionally substituted aromatic.

By “imino” is meant a —NR-group. In some embodiments, R is selected from hydrogen, optionally substituted aliphatic, optionally substituted heteroaliphatic, optionally substituted aromatic, or optionally substituted heteroaromatic. In particular embodiments, R is H, optionally substituted alkyl, optionally substituted alkoxy, optionally substituted aryl, optionally substituted aryloxy, optionally substituted alkyl-aryl, or optionally substituted aryl-alkyl.

By “isocyanato” is meant a —NCO group.

By “isocyano” is meant a —NC group.

By “ketone” is meant —C(O)R or a compound including such a group, where R is selected from aliphatic, heteroaliphatic, aromatic, as defined herein, or any combination thereof. An example of a ketone can include R¹C(O)R, in which each of R and R¹ is, independently, selected from aliphatic, haloaliphatic, haloheteroaliphatic, heteroaliphatic, aromatic, aliphatic-aromatic, heteroaliphatic-aromatic, as defined herein, or any combination thereof.

By “nitro” is meant an —NO₂ group.

By “nitroalkyl” is meant an alkyl group, as defined herein, substituted by one to three nitro groups. In some embodiments, the nitroalkyl group is —L—NO, in which L is an alkyl group, as defined herein. In other embodiments, the nitroalkyl group is —L—C(NO)(R¹)—R², in which L is a covalent bond or an alkyl group, as defined herein, and each of R¹ and R² is, independently, H or alkyl, as defined herein.

By “oxo” is meant an ═O group.

By “oxy” is meant —O—.

By “perfluoroalkyl” is meant an alkyl group, as defined herein, having each hydrogen atom substituted with a fluorine atom. Exemplary perfluoroalkyl groups include trifluoromethyl, pentafluoroethyl, etc. In some embodiments, the perfluoroalkyl group is —(CF₂)ₙCF₃, in which n is an integer from 0 to 10.

By “perfluoroalkoxy” is meant an alkoxy group, as defined herein, having each hydrogen atom substituted with a fluorine atom. In some embodiments, the perfluoroalkoxy group is —O—R, in which R is a perfluoroalkyl group, as defined herein.

By “salt” is meant an ionic form of a compound or structure (e.g., any formulas, compounds, or compositions described herein), which includes a cation or anion compound to form an electrically neutral compound or structure. Salts are well known in the art. For example, non-toxic salts are described in Berge S. M. et al., “Pharmaceutical salts,” J. Pharm. Sci. 1977 January; 66 (1): 1-19; and in “Handbook of Pharmaceutical Salts: Properties, Selection, and Use,” Wiley-VCH, April 2011 (2nd rev. ed., eds. P. H. Stahl and C. G. Wermuth. The salts can be prepared in situ during the final isolation and purification of the compounds of the invention or separately by reacting the free base group with a suitable organic acid (thereby producing an anionic salt) or by reacting the acid group with a suitable metal or organic salt (thereby producing a cationic salt). Representative anionic salts include acetate, adipate, alginate, ascorbate, aspartate, benzenesulfonate, benzoate, bicarbonate, bisulfate, bitartrate, borate, bromide, butyrate, camphorate, camphorsulfonate, chloride, citrate, cyclopentanepropionate, digluconate, dihydrochloride, diphosphate, dodecylsulfate, edetate, ethanesulfonate, fumarate, glucoheptonate, gluconate, glutamate, glycerophosphate, hemisulfate, heptonate, hexanoate, hydrobromide, hydrochloride, hydroiodide, hydroxyethanesulfonate, hydroxynaphthoate, iodide, lactate, lactobionate, laurate, lauryl sulfate, malate, maleate, malonate, mandelate, mesylate, methanesulfonate, methylbromide, methylnitrate, methylsulfate, mucate, 2-naphthalenesulfonate, nicotinate, nitrate, oleate, oxalate, palmitate, pamoate, pectinate, persulfate, 3-phenylpropionate, phosphate, picrate, pivalate, polygalacturonate, propionate, salicylate, stearate, subacetate, succinate, sulfate, tannate, tartrate, theophyllinate, thiocyanate, triethiodide, toluenesulfonate, undecanoate, valerate salts, and the like. Representative cationic salts include metal salts, such as alkali or alkaline earth salts, e.g., barium, calcium (e.g., calcium edetate), lithium, magnesium, potassium, sodium, and the like; other metal salts, such as aluminum, bismuth, iron, and zinc; as well as nontoxic ammonium, quaternary ammonium, and amino cations, including, but not limited to ammonium, tetramethylammonium, tetraethylammonium, methylamine, dimethylamine, trimethylamine, triethylamine, ethylamine, pyridinium, and the like. Other cationic salts include organic salts, such as chloroprocaine, choline, dibenzylethylenediamine, diethanolamine, ethylenediamine, methylglucamine, and procaine. Yet other salts include ammonium, sulfonium, sulfoxonium, phosphonium, iminium, imidazolium, benzimidazolium, amidinium, guanidinium, phosphazinium, phosphazenium, pyridinium, etc., as well as other cationic groups described herein (e.g., optionally substituted isoxazolium, optionally substituted oxazolium, optionally substituted thiazolium, optionally substituted pyrrolium, optionally substituted furanium, optionally substituted thiophenium, optionally substituted imidazolium, optionally substituted pyrazolium, optionally substituted isothiazolium, optionally substituted triazolium, optionally substituted tetrazolium, optionally substituted furazanium, optionally substituted pyridinium, optionally substituted pyrimidinium, optionally substituted pyrazinium, optionally substituted triazinium, optionally substituted tetrazinium, optionally substituted pyridazinium, optionally substituted oxazinium, optionally substituted pyrrolidinium, optionally substituted pyrazolidinium, optionally substituted imidazolinium, optionally substituted isoxazolidinium, optionally substituted oxazolidinium, optionally substituted piperazinium, optionally substituted piperidinium, optionally substituted morpholinium, optionally substituted azepanium, optionally substituted azepinium, optionally substituted indolium, optionally substituted isoindolium, optionally substituted indolizinium, optionally substituted indazolium, optionally substituted benzimidazolium, optionally substituted isoquinolinum, optionally substituted quinolizinium, optionally substituted dehydroquinolizinium, optionally substituted quinolinium, optionally substituted isoindolinium, optionally substituted benzimidazolinium, and optionally substituted purinium).

By “silyl” is meant a —SiR¹R²R³ or —SiR¹R²— group. In some embodiments, each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyl group is —Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

By “silyloxy” is meant —OR, where R is an optionally substituted silyl group, as described herein. In some embodiments, the silyloxy group is —O—SiR¹R²R³, in which each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyloxy group is —O—Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl

By “sulfinyl” is meant an —S(O)—group.

By “sulfo” is meant an —S(O)₂OH group.

By “sulfonyl” or “sulfonate” is meant an —S(O)₂-group or a —SO₂R, where R is selected from hydrogen, aliphatic, heteroaliphatic, haloaliphatic, haloheteroaliphatic, aromatic, as defined herein, or any combination thereof.

By “thioalkyl” is meant an alkyl group, as defined herein, attached to the parent molecular group through a sulfur atom. Exemplary unsubstituted thioalkyl groups include C₁₋₆ thioalkyl. In some embodiments, the thioalkyl group is —S—R, in which R is an alkyl group, as defined herein.

By “thiol” is meant an —SH group.

A person of ordinary skill in the art would recognize that the definitions provided above are not intended to include impermissible substitution patterns (e.g., methyl substituted with 5 different groups, and the like). Such impermissible substitution patterns are easily recognized by a person of ordinary skill in the art. Any functional group disclosed herein and/or defined above can be substituted or unsubstituted, unless otherwise indicated therein.

As used herein, the term “about” means +/−10% of any recited value. As used herein, this term modifies any recited value, range of values, or endpoints of one or more ranges.

As used herein, the terms “top,” “bottom,” “upper,” “lower,” “above,” and “below” are used to provide a relative relationship between structures. The use of these terms does not indicate or require that a particular structure must be located at a particular location in the apparatus.

Other features and advantages of the invention will be apparent from the following description and the claims.

### Silicon-Containing Precursors

In various embodiments, the silicon-containing precursor is a silane. Silanes include but are not limited to substituted and unsubstituted silanes, halosilanes, aminosilanes, organosilanes, alkylsilanes, alkylaminosilanes, and alkylhalosilanes. In particular embodiments, the silicon-containing precursor includes a halosilane precursor. In particular embodiments, the silicon-containing precursor includes an aminosilane precursor.

An aminosilane includes at least one nitrogen atom bonded to a silicon atom, but may also contain hydrogens, oxygens, halogens and carbons. Examples of aminosilanes are mono-, di-, tri- and tetra-aminosilane (H₃Si(NH₂)₄, H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tertiarybutylamino) silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃, di(sec-butylamino) silane (DSBAS), di(isopropylamino) silane (DIPAS), bis(diethylamino) silane (BDEAS), and the like. A further example of an aminosilane is trisilylamine (N(SiH₃)₃). In one example, the silicon-containing precursor is DIPAS. In another example, the silicon-containing precursor is BTBAS.

A silicon-containing precursor can include one or more optionally substituted amino groups, thereby providing a non-limiting amino silane. In one embodiment, the precursor has a formula of

(R′)₄₋ₓSi(NR″₂)ₓ,

wherein:
x is 1, 2, 3, or 4;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In another embodiment, the precursor has a formula of

(R″₂N)ₓ(R′)₃₋ₓSi—L—Si(R′)₃₋ₓ(NR″₂)ₓ,

wherein:
each x is, independently, 0, 1, 2, or 3;
L is a linker, such as a covalent bond, optionally substituted aliphatic, optionally substituted heteroaliphatic, optionally substituted aromatic, optionally substituted heteroaromatic, oxy (—O—), imino, or silyl;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In particular embodiments, L is optionally substituted imino, such as —NR—, in which R is H, optionally substituted aliphatic, optionally substituted alkyl, optionally substituted alkenyl, optionally substituted alkynyl, or optionally substituted aromatic. In other embodiments, L is optionally substituted silyl, such as —SiR₂—, in which each R is, independently, H, optionally substituted aliphatic, optionally substituted alkyl, optionally substituted alkenyl, optionally substituted alkynyl, or optionally substituted aromatic.

In one instance, at least one x is not 0. In another embodiment, x can be 0 (e.g., if L includes a carbon atom or a heteroatom). In yet another embodiment, x is 0; and/or L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl.

In particular embodiments, at least one R′ or R″ is not H. The precursor can have any useful combination of R′ groups and amino groups (NR″₂) attached to one or more silicon atoms.

In some embodiments, R′ is H, optionally substituted amino (e.g., —NR₂), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O) OR), silyl (e.g., —SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)₆), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl.

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments, R″ is —SiR′₃, —SiR₃, —Si(R′)ₐ(OR)_{b}, —Si(R)ₐ(OR)_{b}, —Si(R′)ₐ(NR₂)_{b}, —Si(R)ₐ(NR₂)_{b}, —Si(R′)ₐ(OR)_{b} (NR₂)_{c}, —Si(R)ₐ(OR)_{b} (NR₂)_{c}, —O—SiR′₃, —O—SiR₃, —O—Si(R′)ₐ(OR)_{b}, —O—Si(R)ₐ(OR)_{b}, —O—Si(R′)ₐ(NR₂)_{b}, —O—Si(R)ₐ(NR₂)_{b}, —O—Si(R′)ₐ(OR)₄(NR₂)_{c}, or —O—Si(R)ₐ(OR)_{b} (NR₂)_{c} in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c>0; and a+b+c=3 or a +b=3 (if c is not present). In particular embodiments, R is H, optionally substituted alkyl, optionally substituted alkenyl, or optionally substituted alkynyl.

The precursor can include at least one R′ group attached to the silicon atom. In one embodiment, the precursor has a formula of

(R′)(H)₃₋ₓSi(NR″₂)ₓ,

wherein R′ and R″ can be any described herein, and wherein x is 1, 2, or 3. In another embodiment, the precursor has a formula of

(R′)(H)₂Si(NR″₂),

wherein R′ and R″ can be any described herein. In one embodiment, the precursor has a formula of

(R′)(H)Si(NR″₂)₂,

wherein R′ and R″ can be any described herein. In another embodiment, the precursor has a formula of

(R′)₂(H)Si(NR″₂),

wherein R′ and R″ can be any described herein. In yet another embodiment, the precursor has a formula of

(R′)₂Si(NR″₂)₂,

wherein R′ and R″ can be any described herein. In one embodiment, the precursor has a formula of

(R′);Si(NR″₂),

wherein R′ and R″ can be any described herein.

The precursor can lack an R′ group attached to the silicon atom. In one embodiment, the precursor has a formula of

(H)₄₋ₓSi(NR″₂)ₓ,

wherein each R″ can independently be any described herein, and wherein x is 1, 2, 3, or 4. In another embodiment, the precursor has a formula of Si(NR″₂)ₓ, wherein each R″ can independently be any described herein. In particular embodiments, each R″ is, independently, aliphatic, heteroaliphatic, aromatic, or heteroaromatic.

The precursor can include one or more hydrogen atoms attached to the silicon atom. In one embodiment, the precursor has a formula of

(H)₃Si(NR″₂) or(H)₂Si(NR″₂)₂

or

(H)Si(NR″₂)₃,

wherein each R″ can independently be any described herein. In particular embodiments, each R″ is, independently, aliphatic, heteroaliphatic, aromatic, heteroaromatic, or amino, in which any of these may be optionally substituted.

The precursor can include a heterocyclyl group having a nitrogen atom. In one embodiment, the formula has a formula of H₃Si—Het, in which Het is an optionally substituted heterocyclyl including at least one nitrogen atom. In particular embodiments, the precursor has a formula of

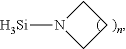

in which the heterocyclyl group can be optionally substituted (e.g., with any substituent described herein as a substitution for alkyl), and wherein n is 1,2, 3, 4, or 5. In one embodiment, the formula has a formula of R′₃Si—Het, in which Het is an optionally substituted heterocyclyl including at least one nitrogen atom, and each R′ can independently be any described herein. In particular embodiments, the precursor has a formula of

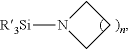

in which the heterocyclyl group can be optionally substituted (e.g., with any substituent described herein as a substitution for alkyl); each R′ can independently be any described herein; and wherein n is 1,2, 3, 4, or 5.

In some instances, the precursor can have two or more silicon atoms, in which the precursor can include a Si—Si bond. In a particular embodiment, the precursor has a formula of

(R″₂N)ₓ(R′)₃₋ₓSi—Si(R′)₃₋ₓ(NR″₂)ₓ,

wherein R′ and R″ can be any described herein. In one embodiment, the precursor has a formula of

(R″₂N)(R′)₂Si—Si(R′)₂(NR″₂),

wherein R′ and R″ can be any described herein. In another embodiment, the precursor has a formula of

(R″₂N)₂(R′)Si—Si(R′)(NR″₂)₂,

wherein R′ and R″ can be any described herein. In yet another embodiment, the precursor has a formula of

(R″₂N)₃Si—Si(NR″₂)₃,

wherein each R″ can independently be any described herein.

The precursor can include differing groups attached to the silicon atoms. In one instance, the precursor has a formula of

(R″₂N)ₓ(R′)₃₋ₓSi—SiH₃,

wherein R′ and R″ can be any described herein.

A linker can be present between two silicon atoms. In one instance, the precursor has a formula of

(R″₂N)ₓ(R′)₃₋ₓSi—NR—Si(R′)₃₋ₓ(NR″₂)ₓ,

wherein R′ and R″ can be any described herein, and in which R is H, optionally substituted aliphatic, optionally substituted alkyl, optionally substituted alkenyl, optionally substituted alkynyl, or optionally substituted aromatic. In another instance, the precursor has a formula of

(R″₂N)ₓ(H)₃₋ₓSi—NR—Si(H)₃₋ₓ(NR″₂)ₓ,

wherein R, R′, and R″ can be any described herein.

The precursor can include a combination of R′ groups with a linker having a heteroatom. In one instance, the precursor has a formula of (R′); Si—NR—Si(R′)₃, wherein R and R′ can be any described herein. In another instance, the precursor has a formula of (R′)₃Si—L—Si(R′)₃, wherein L and R′ can be any described herein. In particular embodiments, L is oxy (—O—), optionally substituted imino (e.g., —NR—), or optionally substituted silyl (e.g., —SiR₂—).

The precursor can include any useful combination of R′ and NR″₂ groups in combination with two silicon atoms. In one instance, the precursor has a formula of

(R″₂N)(R′)₂Si—L—Si(R′)₂(NR″₂)ₓ,

wherein L, R′, and R″ can be any described herein.

The precursor can include heterocyclic groups including the silicon and nitrogen atoms.

In one embodiment, the precursor has a formula of

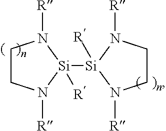

wherein R′ and R″ can be any described herein, and wherein n is 1, 2, 3, or 4. In another embodiment, the precursor has a formula of

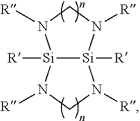

wherein R′ and R″ can be any described herein, and wherein n is 1, 2, 3, or 4. In yet another embodiment, the precursor has a formula of

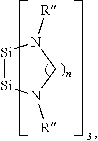

in which each R″ can independently be any described herein; and wherein n is 1,2, 3, or 4. In another embodiment, the precursor has a formula of

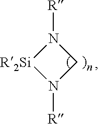

wherein R′ and R″ can be any described herein, and wherein n is 1, 2, 3, or 4. In yet another embodiment, the precursor has a formula of

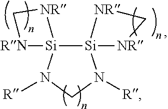

wherein R″ can independently be any described herein, and wherein n is 1, 2, 3, or 4.

In any precursor herein, two R″ can be taken together, with the nitrogen atom to which each is attached, to form an optionally substituted heterocyclyl.

Precursors can include any of the following, e.g., (R^{Ak}) Si(NH₂)(NR^{Ak}₂)₂, (R^{Ak}) Si(NR^{Ak}₂)₃, (R^{Ak})₂Si(NHR^{Ak}₂)₂, (R^{Ak})(H) Si(NHR_{Ak})₂, (R^{Ak}); Si(NR^{Ak}₂), (R^{Ak}); Si(NHR_{Ak}), H₂Si(NHR^{Ak}₂)₂, (R^{Ak})(H) Si(NR^{Ak}₂)₂, HSi(NH₂)(NR^{Ak}₂)₂, HSi(NR^{Ak}₂)₃, Si(NR^{Ak}₂)₄, (R′)(H) Si(NR″₂)₂, (R′)₂Si(NR^{Ak}₂)₂, (R′)₂Si(N [SiH₃]₂)₂, (R′)₂Si(N [SiR″₃]₂)₂, or (R′); Si(NHR^{Ak}). In some embodiments, each of R′ and R″, independently, can be any described herein (e.g., H, optionally substituted aliphatic, optionally substituted heteroaliphatic, optionally substituted alkyl, optionally substituted alkenyl, or optionally substituted alkynyl). In other embodiments, each R^{AK} is, independently, H, optionally substituted aliphatic, optionally substituted heteroaliphatic, optionally substituted alkyl, optionally substituted alkenyl, or optionally substituted alkynyl. In particular embodiments, R^{AK} is methyl (Me), ethyl (Et), n-propyl(nPr), iso-propyl(iPr), n-butyl(nBu), sec-butyl(sBu), iso-butyl(iBu), tert-butyl(tBu), and the like. Non-limiting examples of precursor include any of the following: 1 methylaminotrimethylsilane (SiMe; [NHMe]); dimethylaminodimethylsilane (SiMe₂H [NMe₂]); dimethylaminotrimethylsilane (SiMe; [NMe₂]); dimethylaminodiethylsilane (SiHEt₂ [NMe₂]); dimethylaminotriethylsilane (SiEt₃ [NMe₂]); ethylmethylaminodimethylsilane (SiHMe₂ [NMeEt]); 1 ethylmethylaminotrimethylsilane (SiMe₃ [NMeEt]); ethylmethylaminodiethylsilane (SiHEt₂ [NMeEt]); ethylmethylaminotriethylsilane (SiEt₃ [NMeEt]); diethylaminomethylsilane (SiH₂Me[NEt₂]); diethylaminoethylsilane (SiH₂Et[NEt₂]); ethylaminotrimethylsilane (SiMe₃ [NHEt]); diethylaminodimethylsilane (SiHMe₂ [NEt₂]); diethylaminodiethylsilane (SiHEt₂ [NEt₂]); diethylaminotrimethylsilane (SiMe₃ [NEt₂]); diethylaminotriethylsilane (SiEt₃ [NEt₂]); iso-propylaminodimethylsilane (SiHMe₂ [NHiPr]); iso-propylaminotrimethylsilane (SiMe₃ [NHiPr]); iso-propylaminodiethylsilane (SiHEt₂ [NHiPr]); iso-propylaminotriethylsilane (SiEt₃ [NHiPr]); di-isopropylaminotrimethylsilane (SiMe₃ [NiPr₂]); di-iso-propylaminosilane (SiH₃ [NiPr₂], C₆H₁NSi, or DIPAS); di-iso-propylaminomethylsilane (SiH₂Me[NiPr₂]); di-isopropylaminodimethylsilane (SiHMe₂ [NiPr₂]); di-isopropylaminodiethylsilane (SiHEt₂ [NiPr₂]); di-isopropylaminotriethylsilane (SiEt₃ [NiPr₂]); n-propylaminotrimethylsilane (SiMe₃ [NHnPr]); di-sec-butylaminosilane (SiH₃ [NsBu₂] or DSBAS); di-sec-butylaminomethylsilane (SiH₂Me[NsBu₂]); iso-butylaminotrimethylsilane (SiMe; [NHiBu]); n-butylaminotrimethylsilane (SiMe; [NHnBu]); tert-butylaminodimethylsilane (SiHMe₂ [NHtBu]); tert-butylaminotrimethylsilane (SiMe₃ [NHtBu]); tert-butylaminodiethylsilane (SiHEt₂ [NHtBu]); tert-butylaminotriethylsilane (SiEt₃ [NHtBu]); dicyclohexylaminosilane (SiH₃ [NCy₂], in which Cy is cyclohexyl); N-propylisopropylaminosilane (SiH₃ [NiPrnPr]); N-methylcyclohexylaminosilane (SiH₃ [NMeCy]); N-ethylcyclohexylaminosilane (SiH₃ [NEtCy]); allylphenylaminosilane (SiH₃ [NAllPh]); N-isopropylcyclohexylaminosilane (SiH₃ [NiPrCy]); allylcyclopentylaminosilane (SiH₃ [NAllCp]); phenylcyclohexylaminosilane (SiH₃ [NPhCy]); cyclohexylaminotrimethylsilane (SiMe₃ [NHCy], in which Cy is cyclohexyl); pyrrolyltrimethylsilane (SiMe₃ [NHPy], in which Py is pyrrolyl); pyrrolidinotrimethylsilane (SiMe₃ [NHPyr], in which Pyr is pyrrolindyl); piperidino trimethylsilane (SiMe₃ [NHPip], in which Pip is piperidinyl); piperazinotrimethylsilane (SiMe; [NHPz], in which Pz is piperazinyl); imidazolyltrimethylsilane (SiMe; [NHIm], in which Im is imidazolyl); bis(dimethylamino) silane (SiH₂ [NMe₂]₂ or BDMAS); bis(dimethylamino) methylsilane (SiMeH [NMez]₂); bis(dimethylamino) dimethylsilane (SiMe₂ [NMe₂]₂ or BDMADMS); bis(dimethylamino) diethylsilane (SiEt₂ [NMe₂]₂); bis(dimethylamino) methylvinylsilane (SiMe Vi[NMe₂]₂); bis(ethylamino) dimethylsilane (SiMe₂ [NHEt]₂); bis(ethylmethylamino) silane (SiH₂ [NMeEt]₂); bis(ethylmethylamino) dimethylsilane (SiMe₂ [NMeEt]₂); bis(ethylmethylamino) diethylsilane (SiEt₂ [NMeEt]₂); bis(ethylmethylamino) methylvinylsilane (SiMeVi[NMeEt]₂); bis(diethylamino) silane (SiH₂ [NEt₂]₂, CSH₂₂N₂Si, or BDEAS); bis(diethylamino) dimethylsilane (SiMe₂ [NEt₂]₂); bis(diethylamino) methylvinylsilane (SiMeVi[NEt₂]₂); bis(diethylamino) diethylsilane (SiEt₂ [NEt₂]₂); bis(iso-propylamino) dimethylsilane (SiMe₂ [NHiPr]₂); bis(iso-propylamino) diethylsilane (SiEt₂ [NHiPr]₂); bis(iso-propylamino) methylvinylsilane (SiMeVi[NHiPr]₂); bis(di-iso-propylamino) silane (SiH₂ [NiPr₂]₂); bis(di-iso-propylamino) dimethylsilane (SiMe₂ [NiPr₂]₂); bis(di-iso-propylamino) diethylsilane (SiEt₂ [NiPr₂]₂); bis(di-iso-propylamino) methylvinylsilane (SiMe Vi[NiPr₂]₂); bis(methylamino) silane (SiH₂ [NHMe]₂); bis(sec-butylamino) silane (SiH₂ [NHsBu]₂); bis(sec-butylamino) methylsilane (SiHMe[NHsBu]₂); bis(sec-butylamino) ethylsilane (SiHEt[NHsBu]₂); bis(tert-butylamino) silane (SiH₂ [NHtBu]₂ or BTBAS); bis(tert-butylamino) dimethylsilane methylvinylsilane (SiMe Vi[NHtBu]₂); bis(tert-(SiMe₂ [NHtBu]₂); bis(tert-butylamino) butylamino) diethylsilane (SiEt₂ [NHtBu]₂); bis(1-imidazolyl) dimethylsilane (SiMe₂ [Im]₂, in which Im is imidazolyl); tris(dimethylamino) silane (SiH [NMe₂]₃ or 3DMAS); tris(dimethylamino)phenylsilane (SiPh[NMe₂]₃); tris(dimethylamino) methylsilane (SiMe[NMe₂]₃); tris(dimethylamino)ethylsilane (SiEt[NMe₂]₃); tris(ethylmethylamino) silane (SiH [NEtMe]₃); tris(diethylamino) silane (SiH [NEt₂]₃); tris(iso-propylamino) silane (SiH [NHiPr]₃, C₉H₂₅N₃Si, or TIPAS); tris(dimethylamino) silylamide (Si[NMe₂]₃ [NH₂]); tetrakis(dimethylamino) silane (Si[NMe₂]₄); tetrakis(ethylmethylamino) silane (Si[NEtMe]₄); tetrakis(diethylamino) silane (Si[NEt₂]₄); 1,2-diethyl-tetrakis(diethylamino) disilane ([Et₂N]₂EtSi—SiEt[NEt₂]₂); 1,2-dimethyl-tetrakis(dimethylamino) disilane ([Me₂N]₂MeSi—SiMe[NMe₂]₂); 1,2-dimethyl-tetrakis(diethylamino) disilane ([Et₂N]₂MeSi—SiMe[NEt₂]₂); hexakis(methylamino) disilane ([MeHN]₃Si—Si[NHMe]₃); hexakis (ethylamino) disilane ([EtHN]₃Si—Si[NHEt]₃); hexakis (dimethylamino) disilazane (Me₂N—Si[NMez]₂—Si[NMe₂]₂—NMe₂), and the like.

In some embodiments, the silane precursor is a halosilane precursor. A halosilane precursor is defined as a precursor having at least one halogen-containing atom and at least one silicon atom. Halogens include chlorine, fluorine, bromine, and iodine. In some embodiments, the halosilane precursor includes a structure of formula (I):

Si(X)₄,

wherein at least one X includes a halogen atom.

For example, one halosilane is tetrachlorosilane or silicon tetrachloride (SiCl₄). Another example of a chemical formula of a halosilane is SiₙX_{y}H_{z}, where X is a halogen and His hydrogen; n is an integer greater than or equal to 1 and is equal to the number of Si atoms in the molecule; in some embodiments, y is about 1 to about 4, and z is 4-y. Additional examples include but are not limited to SiHCl₃, SiH₂Cl₂, and SiH₃Cl.

Examples of halosilanes are iodosilanes, bromosilanes, chlorosilanes and fluorosilanes. Specific chlorosilanes include but are not limited to tetrachlorosilane, trichlorosilane, dichlorosilane (DCS), monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, hexachlorodisilane (HCDS), and the like.

In some embodiments, the halosilane is carbon-free. In some embodiments, the halosilane is an organic silicon-containing precursor.

In some embodiments, the halosilane precursor (e.g., in formula (I)) has at least one optionally substituted C₁₋₂ haloalkyl group. Non-limiting haloaliphatic groups include —CₓH_{3-y}, wherein y is 1, 2, or 3, and wherein each X is, independently, halo(F, Cl, Br, or I); —CₓH_{2-z}CₓH_{3-y}, wherein z is 0, 1, or 2, wherein y is 0, 1, 2, or 3, and wherein each X is, independently, halo(F, Cl, Br, or I), in which at least one of z or y is not 0; or —CH₂CX_{y}H_{3-y}, wherein y is 1, 2, or 3, and wherein each X is, independently, halo(F, Cl, Br, or I). Yet other non-limiting haloalkyl groups include fluoromethyl (—CH₂F), difluoromethyl (—CHF₂), trifluoromethyl (—CF₃), chloromethyl (—CH₂Cl), dichloromethyl (—CHCl₂), trichloromethyl (—CCl₃), bromomethyl (—CH₂Br), dibromomethyl (—CHBr₂), tribromomethyl (—CBr₃), iodomethyl (—CH₂I), diiodomethyl (—CHI₂), triiodomethyl (—Cl₃), bromofluoromethyl (—CHFBr), chlorofluoromethyl (—CHFCl), fluoroiodomethyl (—CHFl), 2-fluoroethyl (—CH₂CH₂F), 2-chloroethyl (—CH₂CH₂Cl), 2-bromoethyl (—CH₂CH₂Br), 2-iodoethyl (—CH₂CH₂I), 2,2-difluoroethyl (—CH₂CHF₂), 2,2-dichloroethyl (—CH₂CHCl₂), 2,2-dibromoethyl (—CH₂CHBr₂), 2,2-diiodoethyl (—CH₂CHI₂), 2,2-fluoroiodoethyl (—CH₂CHFI), and the like. In particular embodiments, the C₁₋₂ haloalkyl includes β-halo-substituted ethyl. Yet other haloaliphatic groups include C₁₋₄ haloalkyl, C₂₋₄ haloalkenyl, and C₂₋₄ haloalkynyl.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method for processing substrates, the method comprising:
providing a substrate having a dielectric material deposited thereon;
depositing a protective layer on the dielectric material in a plasma-free environment; and
after depositing the protective layer, exposing the substrate to a first plasma to deposit a first silicon nitride while converting at least a portion of the protective layer to second silicon nitride.

2. The method of claim 1, wherein the protective layer is deposited by thermally decomposing a deposition precursor on a surface of the substrate.

3. The method of claim 1, wherein the protective layer is deposited by exposing the substrate to a deposition precursor; and heating the substrate to a temperature sufficient to decompose the deposition precursor onto a surface of the substrate.

4. The method of claim 1, wherein the protective layer is deposited by temporally alternating pulses of exposing the substrate to a deposition precursor; and exposing the substrate to an inert gas.

5. The method of claim 1, wherein exposing the substrate to the first plasma comprises generating the first plasma using one or more nitrogen-containing gases.

6. The method of claim 1, wherein the protective layer is deposited by decomposing a deposition precursor on a surface of a substrate to form a decomposed film; and exposing the decomposed film to a second plasma to form the protective layer.

7. The method of claim 3, wherein the deposition precursor is diisopropylaminosilane or bis(tertiarybutylamino) silane.

8. A method for processing substrates, the method comprising:
providing a substrate having a silicon oxynitride material deposited thereon to a process chamber;
introducing a first silicon-containing precursor to the process chamber at process conditions sufficient to decompose the first silicon-containing precursor and form decomposed first silicon-containing precursor on a surface of the substrate in a plasma-free environment to form a protective layer comprising the decomposed first silicon-containing precursor;
after forming the protective layer, introducing a second silicon-containing precursor to the process chamber to form an adsorbed layer of the second silicon-containing precursor on a surface of the protective layer; and
introducing a nitrogen-containing plasma to the process chamber to convert the second silicon-containing precursor to silicon nitride and convert at least a portion of the protective layer to silicon nitride.

9. The method of claim 8, wherein at least one of the first and the second silicon-containing precursors is diisopropylaminosilane or bis(tertiarybutylamino) silane.

10. An apparatus for processing substrates, the apparatus comprising:
one or more process chambers, each process chamber comprising a chuck;
one or more gas inlets into the process chambers and associated flow-control hardware; and
a controller having at least one processor and a memory, wherein
the at least one processor and the memory are communicatively connected with one another, the at least one processor is at least operatively connected with the flow-control hardware, and
the memory stores computer-executable instructions for controlling the at least one processor to at least control the flow-control hardware to:
cause introduction of a first silicon-containing precursor to the one or more process chambers for a duration sufficient to adsorb at least some of the first silicon-containing precursor to adsorb to a surface of a substrate without igniting a plasma;
cause heating of the chuck to decompose the first silicon-containing precursor and form a protective layer on the surface of the substrate;
cause introduction of a second silicon-containing precursor to the one or more process chambers for a duration sufficient to adsorb at least some of the second silicon-containing precursor to adsorb to a surface of a substrate without igniting a plasma; and
cause generation of a plasma using a nitrogen-containing gas both convert the second silicon-containing precursor to silicon nitride and convert at least a portion of the protective layer to silicon nitride.
